(19) United States
(12) Patent Application Publication
(10) Pub. No.: US 2016/0260772 A1
(43) Pub. Date: Sep. 8, 2016

(54) SEMICONDUCTOR DEVICE AND METHOD OF MANUFACTURING SAME

(71) Applicant: Renesas Electronics Corporation, Tokyo (JP)

(72) Inventors: Tatsuya USAMI, Ibaraki (JP); Yukio MIURA, Ibaraki (JP)

(73) Assignee: Renesas Electronics Corporation, Tokyo (JP)

(21) Appl. No.: 15/047,746

(22) Filed: Feb. 19, 2016

(30) Foreign Application Priority Data
Mar. 6, 2015 (JP) 2015-045325

(51) Int. Cl. H01L 27/22; H01L 43/10; H01L 43/02; H01L 43/12; H01L 43/08

(52) U.S. Cl. CPC H01L 27/222; H01L 43/12; H01L 43/08; H01L 43/02; H01L 43/10

(57) ABSTRACT

To provide a magnetoresistance effect element configuring MRAM by dry etching and thereby processing a stacked film including magnetic layers, in order to prevent a leakage current from flowing between the magnetic layers, that is, magnetic free layer and magnetic pinned layer which configure a magnetic tunnel junction (MTJ) via a metal deposit that has attached to the side wall of the MTJ. After formation of the magnetoresistance effect element by dry etching, plasma treatment is performed in a gas atmosphere containing carbon and oxygen to remove a metal deposit attached to the magnetoresistance effect element. By this plasma treatment, oxide films are formed on the side walls of the magnetic free layer and the magnetic pinned layer, respectively.

### CROSS-REFERENCE TO RELATED APPLICATIONS

The disclosure of Japanese Patent Application No. 2015-045325 filed on Mar. 6, 2015 including the specification, drawings, and abstract is incorporated herein by reference in its entirety.

### BACKGROUND

The present invention relates to a semiconductor device and a manufacturing method thereof, for example, a technology applicable to the manufacture of a semiconductor device having a magnetoresistance effect element.

Being expected as a nonvolatile memory that can be operated at high speed and is infinitely reprogrammable, a magnetic random access memory (MRAM) has been developed briskly. MRAM uses a magnetic material as a memory element and stores data according to the magnetization direction of the magnetic material. They use, as the memory element, for example, a magnetoresistance effect element having a structure obtained by successively stacking a magnetic free layer, a spacer layer, and a magnetic pinned layer, that is, having a magnetic tunnel junction (MTJ). It is known that, for example, CoFeB is used as a material of the magnetic free layer and the magnetic pinned layer configuring the magnetoresistance effect element.

Patent Document 1 (WO2009/001706) describes the structure and operation principle of MRAM.

### PATENT DOCUMENT

[Patent Document 1] WO2009/001706

### SUMMARY

An object of the present embodiment is to provide a semiconductor device having improved reliability. In particular, when during formation of a magnetoresistance effect element comprised of the above-mentioned stacked structure, the stacked film formed on a semiconductor substrate is patterned by dry etching or the like, a metal substance configuring the magnetic free layer and the magnetic pinned layer obtained by etching may attach to the side wall of the patterned magnetoresistance effect element. In this case, the attached material made of the metal substance becomes a leakage path and, in the magnetoresistance effect element comprised of the above-described stacked structure, a leakage current may flow between the magnetic free layer and the magnetic pinned layer. Flow of such a leakage current causes such a problem that it prevents normal operation of the MRAM.

Another object and novel features will be apparent from the description herein and accompanying drawings.

Typical embodiments among those disclosed herein will next be outlined briefly.

In one embodiment, there is provided a method of manufacturing a semiconductor device including dry etching to form a magnetoresistance effect element having a stacked structure and then subjecting a semiconductor substrate having the magnetoresistance effect element to plasma treatment in a gas atmosphere containing carbon and oxygen.

In another embodiment, there is provided a semiconductor device obtained by covering, with an oxide film, the side wall of a magnetic layer configuring a magnetoresistance effect element having a stacked structure.

The embodiment can provide a semiconductor device having improved reliability. In particular, generation of a leakage current in a magnetoresistance effect element configuring MRAM can be prevented.

### BRIEF DESCRIPTION OF THE DRAWINGS

FIG. 1 is a cross-sectional view of a semiconductor device of First Embodiment;

FIG. 2 is another cross-sectional view of the semiconductor device of First Embodiment;

FIG. 3 is a further cross-sectional view of the semiconductor device of First embodiment;

FIG. 4 is a circuit of a magnetic memory cell of First Embodiment;

FIG. 5 is a perspective view showing a magnetoresistance effect element of First Embodiment;

FIG. 6 is a plan view showing a magnetic layer configuring the magnetoresistance effect element of First Embodiment;

FIG. 7 is a cross-sectional view showing the magnetoresistance effect element of First Embodiment;

FIG. 8 is another plan view showing the magnetic layer configuring the magnetoresistance effect element of First Embodiment;

FIG. 9 is a further plan view showing the magnetic layer configuring the magnetoresistance effect element of First Embodiment;

FIG. 10 is a cross-sectional view of the semiconductor device of First Embodiment during a manufacturing step thereof;

FIG. 11 is a cross-sectional view of the semiconductor device during a manufacturing step following that of FIG. 10;

FIG. 12 is a cross-sectional view of the semiconductor device during a manufacturing step following that of FIG. 11;

FIG. 13 is a cross-sectional view of the semiconductor device during a manufacturing step following that of FIG. 12;

FIG. 14 is a cross-sectional view of the semiconductor device during a manufacturing step following that of FIG. 13;

FIG. 15 is a cross-sectional view of the semiconductor device during a manufacturing step following that of FIG. 14;

FIG. 16 is a cross-sectional view of the semiconductor device during a manufacturing step following that of FIG. 15;

FIG. 17 is a cross-sectional view of the semiconductor device during a manufacturing step following that of FIG. 16;

FIG. 18 is a cross-sectional view of the semiconductor device during a manufacturing step following that of FIG. 17;

FIG. 19 is a cross-sectional view of the semiconductor device during a manufacturing step following that of FIG. 18;

FIG. 20 is a cross-sectional view of the semiconductor device during a manufacturing step following that of FIG. 19;

FIG. 21 is a cross-sectional view of the semiconductor device during a manufacturing step following that of FIG. 20;

FIG. 22 is a cross-sectional view of the semiconductor device during a manufacturing step following that of FIG. 21;

FIG. 23 is a cross-sectional view of the semiconductor device during a manufacturing step following that of FIG. 22;

FIG. 24 is a cross-sectional view of the semiconductor device during a manufacturing step following that of FIG. 23;

FIG. 25 is a cross-sectional view of the semiconductor device during a manufacturing step following that of FIG. 24;

FIG. 26 is a cross-sectional view of the semiconductor device during a manufacturing step following that of FIG. 24;

FIG. 27 is a cross-sectional view of the semiconductor device during a manufacturing step following that of FIG. 25;

FIG. 28 is a cross-sectional view of the semiconductor device during a manufacturing step following that of FIG. 27;

FIG. 29 is a cross-sectional view of the semiconductor device during a manufacturing step following that of FIG. 28;

FIG. 30 is a cross-sectional view of the semiconductor device during a manufacturing step following that of FIG. 28;

FIG. 31 is a cross-sectional view of a semiconductor device of Second Embodiment during a manufacturing step thereof;

FIG. 32 is a cross-sectional view of the semiconductor device during a manufacturing step following that of FIG. 31;

FIG. 33 is a cross-sectional view of the semiconductor device during a manufacturing step following that of FIG. 32;

FIG. 34 is a cross-sectional view of the semiconductor device during a manufacturing step following that of FIG. 33;

FIG. 35 is a cross-sectional view of a semiconductor device of Third Embodiment during a manufacturing step thereof;

FIG. 36 is a cross-sectional view of the semiconductor device during a manufacturing step following that of FIG. 35;

FIG. 37 is a cross-sectional view of the semiconductor device during a manufacturing step following that of FIG. 36;

FIG. 38 is a cross-sectional view of the semiconductor device during a manufacturing step following that of FIG. 37;

FIG. 39 is a cross-sectional view of the semiconductor device during a manufacturing step following that of FIG. 38;

FIG. 40 is a cross-sectional view of a semiconductor device of Comparative Example; and

FIG. 41 is a cross-sectional view of a semiconductor device of another Comparative Example.

### DETAILED DESCRIPTION

Embodiments will hereinafter be described in detail referring to drawings. In all the drawings for describing these embodiments, members having the same function will be identified by the same reference numerals and overlapping descriptions will be omitted. In the following embodiments, a description on the same or similar portion is not repeated in principle unless otherwise particularly necessary.

### First Embodiment

Semiconductor device of the present embodiment and embodiments thereafter are equipped with a magnetic random access memory (MRAM) as a nonvolatile memory (nonvolatile memory element, nonvolatile semiconductor memory device).

### <Structure of Semiconductor Device>

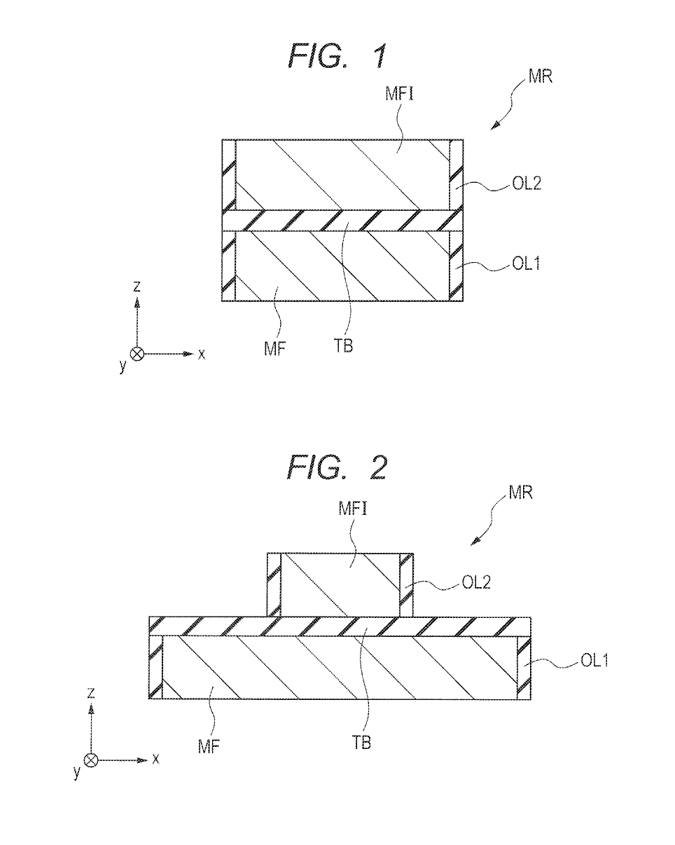

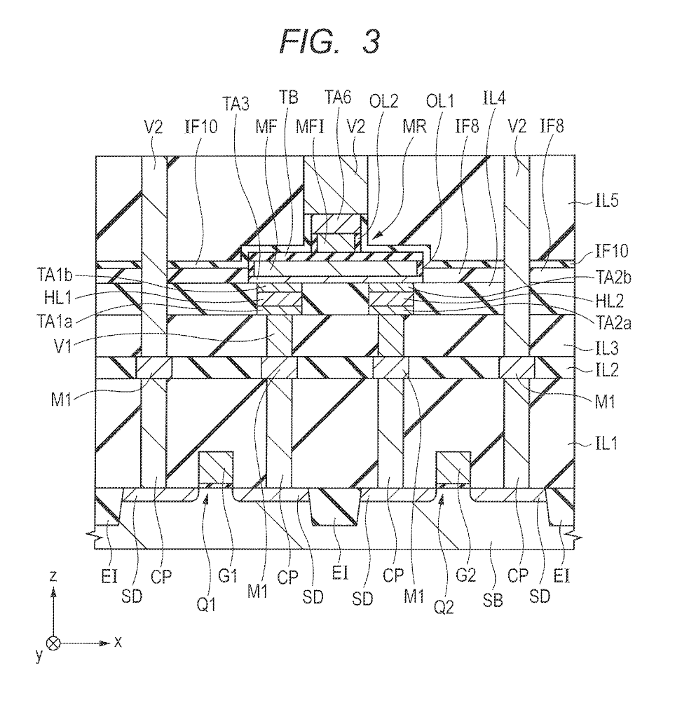

An oxide film is formed on the side wall of a magnetoresistance effect element configuring MRAM by plasma treatment to prevent a leakage current from occurring on the side wall of the magnetoresistance effect element having a stacked structure due to a deposit of a metal substance thereon, which will be described below. First, the structure of the semiconductor device of the present embodiment will be described referring to FIGS. 1 to 3. FIGS. 1 to 3 are cross-sectional views of the semiconductor device of the present embodiment. FIGS. 1 and 2 show the cross-section of a stacked structure which is a characteristic part of the semiconductor device of the present embodiment. FIGS. 1 and 2 show the same stacked structure. The cross-section shown in FIG. 1 and the cross-section shown in FIG. 2 are however different and they perpendicularly intersect with each other. FIG. 3 is a cross-sectional view of the semiconductor device including, in addition to the magnetoresistance effect element shown in FIGS. 1 and 2, a semiconductor substrate, a transistor, wirings, and the like.

FIG. 1 shows a cross-section of a magnetic tunnel junction (MTJ) portion configuring the magnetoresistance effect element MR which is main part of MRAM of the semiconductor device of the present embodiment. The magnetic tunnel junction portion has a stacked structure including a magnetic layer (magnetic free layer) MF, a tunnel barrier layer TB formed formed on the magnetic layer MF, and a magnetic layer (magnetic pinned layer) MFI formed on the tunnel barrier layer TB. The magnetic layer (magnetic free layer) MF is contiguous, at the upper surface thereof, to the lower surface of the tunnel barrier layer TB and the tunnel barrier layer TB is contiguous, at the upper surface thereof, to the lower surface of the magnetic layer (magnetic pinned layer) MFI.

As shown in FIG. 2, the magnetic layer (magnetic free layer) MF configuring the lower portion of the stacked structure extends in a horizontal direction (x-axis direction along the main surface of the semiconductor substrate). In other words, the width of the magnetic layer (magnetic free layer) MF is greater than that of the magnetic layer (magnetic pinned layer) MFI in a direction perpendicular to the stacking direction of the magnetic layer (magnetic free layer) MF, the tunnel barrier layer TB, and the magnetic layer (magnetic pinned layer) MFI.

Similar to the magnetic layer (magnetic free layer) MF, the tunnel barrier layer TB extends in the x-axis direction and covers the upper surface of the magnetic layer MF. On the other hand, the magnetic layer (magnetic pinned layer) MFI does not extend as the magnetic layer (magnetic free layer) MF does. This means that the upper surface of the magnetic layer MF at both end portions thereof in the x-axis direction is not covered with the magnetic layer MFI and is covered with the tunnel barrier layer TB. The tunnel barrier layer TB may have a width similar to that of the magnetic layer MFI without extending in the above-described direction. In this case, the upper surface of the magnetic layer MF on the side of the magnetic layer MFI in the above-described direction is exposed from the tunnel barrier layer TB.

The magnetic resins MF and MFI are each made of, for example, CoFeB, that is, an alloy containing Co (cobalt), Fe (iron), and B (boron) or NiFe, that is, an alloy containing Ni (nickel) and Fe (iron). The tunnel barrier layer TB is an insulating layer (oxidized magnetic layer) made of, for example, MgO (magnesium oxide) or AlOₓ (0<x<1) (aluminum oxide). The tunnel barrier layer TB is a spacer layer having a role of separating the magnetic layer MF from the magnetic layer MFI and insulating the magnetic layer MF from the magnetic layer MFI. The tunnel barrier layer TB is made of, preferably, a nonmagnetic insulator.

The magnetic layer MF, the tunnel barrier layer TB, and the magnetic layer MFI here functions as a magnetic tunnel junction (MTJ) portion exhibiting a TMR (tunneling magneto resistance) effect. In this case, the magnetic layer MF, the tunnel barrier layer TB, and the magnetic layer MFI function as a spin valve exhibiting a GMR (giant magneto resistance) effect.

One of the main characteristics of the present embodiment is that as shown in FIG. 1, the side wall of the stacked film configuring the magnetoresistance effect element MR is covered with the oxidized insulating film. Described specifically, the side wall of the magnetic layer MF is covered with an oxide film OL1, while the side wall of the magnetic layer MFI is covered with an oxide film OL2. The oxide film OL1 is an insulating film formed by oxidizing the side wall of the magnetic layer MF by plasma treatment and the oxide film OL2 is an insulating film formed by oxidizing the side wall of the magnetic layer MF by plasma treatment. The oxide films OL1 and OL2 are films each containing, for example, CoO (cobalt oxide), FeO (iron oxide), Fe₂O₃ (iron trioxide) or B₂O₃ (boron oxide, diboron trioxide).

Here, as shown in FIG. 2, the upper surface of the magnetic layer MF not covered with the magnetic layer MFI is not oxidized because it is covered with the tunnel barrier layer TB. When the tunnel barrier layer TB does not extend and the upper surface of the magnetic layer MF on the side of the magnetic layer MFI is not covered with the tunnel barrier layer TB, the upper surface of the magnetic layer MF on the side of the magnetic layer MFI is covered with the oxide film OL1 formed by oxidizing the magnetic layer MF by plasma treatment.

Next, referring to FIG. 3, the structure of the semiconductor device of the present embodiment including a semiconductor substrate, the magnetoresistance effect element MR, a selective element thereof, and the like will be described. Since the main characteristic of the present embodiment resides in its magnetoresistance effect element MR, a detailed description on the structure of a transistor, which is a selective element of the magnetoresistance effect element MR, is omitted.

As shown in FIG. 3, the semiconductor substrate SB has, on the main surface thereof, N type MOS (metal oxide semiconductor) transistors (field effect transistors) Q1 and Q2. The respective gate electrodes G1 and G2 of the MOS transistors Q1 and Q2 extend in a backward direction of FIG. 3 (the y-axis direction along the main surface of the semiconductor substrate SB) and are used as a word line.

A pair of source-drain regions SD configures the MOS transistor Q1 and one of the source-drain regions SD is electrically coupled to a magnetic pinned layer HL1 via a contact plug CP and a wiring M1, while the other source-drain region SD is coupled to a bit line via a contact plug CP, a wiring M1, and a via V2. A pair of source-drain regions SD configures the MOS transistor Q2 and one of the source-drain regions SD is electrically coupled to a magnetic pinned layer HL2 via a contact plug CP and a wiring M1, while the other source-drain region SD is coupled to another bit line via a contact plug CP, a wiring M1, and a via V2.

The semiconductor substrate SB has thereon an interlayer insulating film IL1 made of, for example, silicon oxide so as to cover the upper surface of the semiconductor substrate and the MOS transistors Q1 and Q2. A plurality of the contact plugs CP is buried in a plurality of contact holes opened in the interlayer insulating film IL1, respectively. The interlayer insulating film IL1 and the contact plugs CP have upper surfaces planarized to have the same surface level, respectively. They have, on the upper surfaces thereof, an interlayer insulating film IL2 made of, for example, silicon oxide.

The interlayer insulating film IL2 have therein a plurality of wiring trenches penetrating through the interlayer insulating film IL2. The wirings have therein a wiring M1 configuring a first wiring layer. A plurality of wiring layers M1 is each made mainly of copper (Cu) and these wirings M1 have respective bottom surfaces each coupled to the upper surface of the contact plug CP. The interlayer insulating film IL2 and the wirings M1 configure the first wiring layer.

The first wiring layer has thereon an interlayer insulating film IL3 made of, for example, silicon oxide. The interlayer insulating film IL3 has a plurality of via holes that penetrate through the interlayer insulating film IL3. Some of the via holes are filled with a via V1. The other via holes are filled with a portion of a via V2 that penetrates through the interlayer insulating film IL3, an interlayer insulating film IL4 formed successively on the interlayer insulating film IL3, insulating films IF8 and IF10, and an interlayer insulating film IL5. The via V1 is a conductor film electrically coupling the MOS transistors Q1 and Q2 to the magnetoresistance effect element MR. It is made of, for example, copper (Cu). The via V1 and the interlayer insulating film IL3 have respective upper surfaces planarized to have the same surface level. The vias V1 and V2 have bottom surfaces coupled to the upper surfaces of the wirings M1, respectively.

The via V1 and the interlayer insulating film IL3 each have thereon an interlayer insulating film IL4 made of, for example, a silicon nitride film. The interlayer insulating film IL4 has therein trenches that correspond to two vias V1 to expose the upper surfaces of the two vias V1, respectively. This means that the upper surface of the via V1 is exposed from the respective bottom surfaces of the two trenches penetrating through the interlayer insulating film IL4. One of the trenches is filled with a stacked film comprised of a conductor film TA1a, the magnetic pined layer HL1, and another conductor film TA1b formed successively on the via V1. The other trench is filled with a stacked film comprised of a conductor film TA2a, the magnetic pinned layer HL2, and another conductor film TA2b formed successively on the via V1.

The conductor films TA1b and TA2b and the interlayer insulating film IL4 have respective upper surfaces planarized to have the same surface level and the conductor films TA1a and TA2a have bottom surfaces coupled to the upper surfaces of the vias V1, respectively. The conductor films TA1a, TA2a, TA1b, and TA2b are each a conductor film containing, for example, Ta (tantalum) and the magnetic pinned layers HL1 and HL2 are each a magnetic material layer containing, for example, Co (cobalt). The magnetization direction of each of the magnetic pinned layers HL1 and HL2 is a perpendicular direction, that is, a direction parallel to the z-axis direction and the magnetization directions of the magnetic pinned layers HL1 and HL2 are contrary to each other.

The interlayer insulating film IL4 has thereon the magnetoresistance effect element MR described above referring to FIGS. 1 and 2. As described referring to FIG. 2, in the magnetoresistance effect element MR shown in FIG. 3, the magnetic layer MF on the bottom thereof extends in the x-axis direction; the bottom surface of one of the end portions of the magnetic layer MF in the x-axis direction is coupled to the magnetic pinned layer HL1 via the conductor film TA1b; and the bottom surface of the other end portion is coupled to the magnetic pinned layer HL2 via the conductor film TA2b. The magnetic pinned layers HL1 and HL2 each have neither the tunnel barrier layer TB nor the magnetic layer MFI immediately thereabove. The magnetic layer MFI has thereon a conductor film TA6 and a via V2 that penetrates through the interlayer insulating film IL5 is coupled to the upper surface of the conductor film TA6. The via V2 is coupled to a ground line.

Although not illustrated here, the conductor film TA6 is comprised of a stacked film formed on the magnetic layer MFI. The stacked film is comprised of three layers, that is, a conductor film containing, for example, Ta (tantalum), a conductor film containing, for example, Co (cobalt), and a conductor film containing, for example, Ta (tantalum), which are formed successively on the magnetic layer MFI.

The magnetic layer MFI configuring the magnetoresistance effect element MR is coupled to a ground line via the conductor film TA6 and the via V2. In the magnetoresistance effect element MR, the magnetic layer MFI and the magnetic layer MF are insulated from each other by the tunnel barrier layer TB present therebetween. The magnetic layer MF configuring the magnetoresistance effect element MR is, at one of the end portions thereof, coupled to the MOS transistor Q2 via the conductor film TA1b, the magnetic pinned layer HL1, the conductor film TA1a, the via V1, the wiring M1, and the contact plug CP, while it is, at the other end portion, coupled to the MOS transistor Q2 via the conductor film TA2b, the magnetic pinned layer HL2, the conductor film TA2a, the via V1, the wiring M1, and the contact plug CP.

The magnetic layer MF has a side wall covered with the oxide film OL1, while the magnetic layer MFI has a side wall covered with the oxide film OL2. The magnetoresistance effect element MR and the conductor film TA6 thereon are covered with an insulating film IF10 made of, for example, a silicon nitride film. This means that the side wall of the magnetic layer MF and the insulating film IF10 have therebetween the oxide film OL1. The side wall of the magnetic layer MFI and the insulating film IF10 have therebetween the oxide film OL2. The insulating film IF10 has thereon the interlayer insulating film IL5. The via V2 penetrates through the interlayer insulating film IL5 and the insulating film IF10 below the interlayer insulating film IL5 and is coupled to the upper surface of the conductor film TA6.

The interlayer insulating film IL5 and the plurality of the vias V2 have respective upper surfaces planarized to have the same surface level. The insulating film IF10 on the side of the magnetic layer MF and the interlayer insulating film IL4 have therebetween, in the x-axis direction, an insulating film IF8 made of, for example, a silicon nitride film. The height of the upper surface of the insulating film IF8 is equal to the height of the upper surface of the magnetic layer MF or lower than the height of the upper surface of the magnetic layer MF. The magnetoresistance effect element MR and the MOS transistors Q1 and Q2 shown in FIG. 3 configure one memory cell of MRAM.

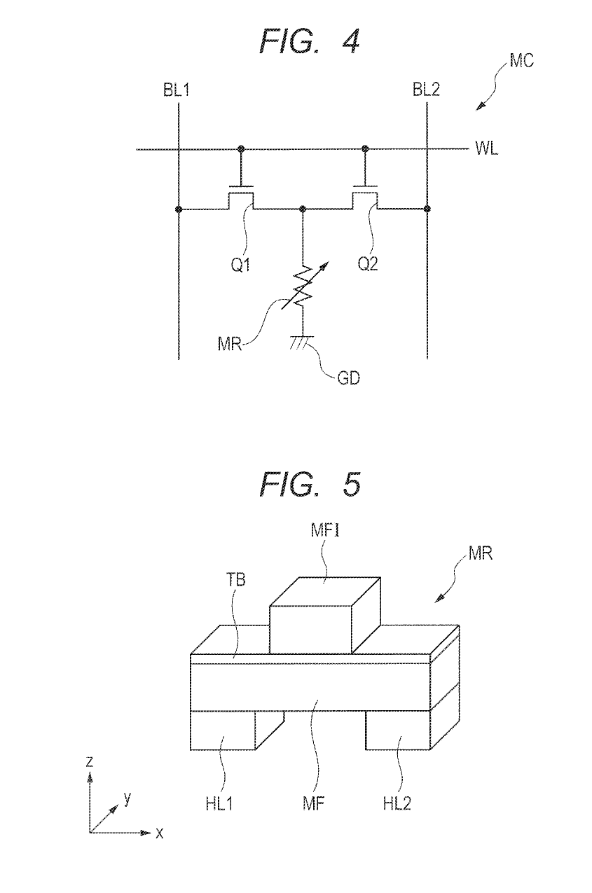

Next, the circuit configuration of a magnetic memory cell MC comprised of the magnetoresistance effect element MR of the present embodiment will be described referring to FIG. 4. FIG. 4 shows the circuit of the magnetic memory cell MC according to the present embodiment. The magnetoresistance effect element MR is a three-terminal element and one of these three terminals to be coupled to the magnetic layer MFI (refer to FIG. 3) is coupled to the ground line GD for reading. Of the two terminals at both ends of the magnetic layer MF (refer to FIG. 3), one is coupled to a first source-drain region of the MOS transistor Q1 and the other one is coupled to a first source-drain region of the MOS transistor Q2.

A second source-drain region of the transistor Q1 is coupled to a bit line BL1 for writing and a second source-drain region of the transistor Q2 is coupled to a bit line BL2 for writing. The gate electrodes of the transistor Q1 are each coupled to a word line WL. The magnetic memory cells MC shown in FIG. 4 are placed in array form, are coupled to a peripheral circuit, and configure a magnetic random access memory (MRAM).

Write and read operations of the magnetic memory cell MC shown in FIG. 4 will next be described. In writing, the word line WL is set “high” and the transistors Q1 and Q2 are turned “ON”. Either one of the bit line BL1 or BL2 is set “high” and the other one is set “low”. The direction of a current flowing in the magnetic layer MF changes, depending on which one between the bit line BL1 and the bit line BL2 is set “high” and which one is set “low”. This enables data to be written in the magnetoresistance effect element MR.

In reading, the word line WL is set “high” and the transistors Q1 and Q2 are turned “ON”. In addition, either one of the bit line BL1 or BL2 is set “high” and the other one is set “open”. At this time, a current flowing through the magnetoresistance effect element MR flows from one of the bit lines BL1 and BL2 to the ground line GD so that this enables data to be read at high speed by making use of the magnetoresistance effect. The circuit shown in FIG. 4 and setting of the circuit described herein are however only one example and they may be replaced by another circuit configuration.

### <Operation of Magnetoresistance Effect Element>

Operation of the magnetoresistance effect element MR will next be described referring to FIGS. 5 to 9. Here, described is the direction of magnetization in a magnetic domain wall displacement type magnetoresistance effect element MR during writing or reading data in the magnetoresistance effect element MR.

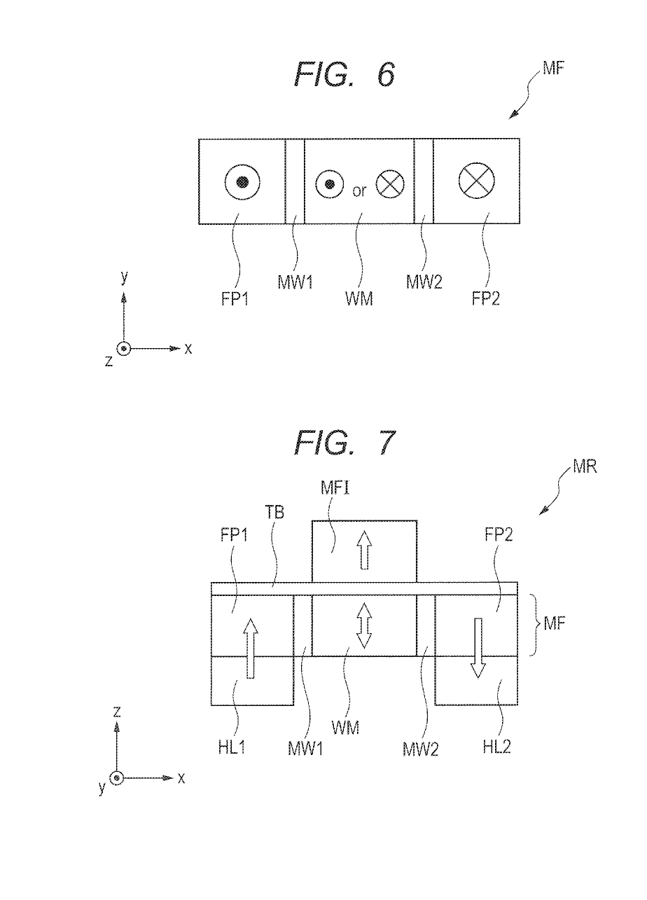

FIG. 5 is a perspective view showing the configuration of a main portion of the magnetoresistance effect element MR of the present embodiment. As shown in FIG. 5, the following description will be made after defining an xyz orthogonal coordinate system. FIGS. 6, 8, and 9 are each an x-y plan view showing the magnetic layer MF configuring the magnetoresistance effect element MR and FIG. 7 is an x-z cross-sectional view showing the configuration of the magnetoresistance effect element MR. To facilitate understanding, FIG. 7 is not hatched. FIGS. 5 to 9 omit the oxide films OL1 and OL2 (refer to FIG. 2). The magnetic pinned layers HL1 and HL2 contiguous to the respective lower surfaces at both ends of the magnetic layer MF are shown to facilitate understanding of them. In fact, as described above referring to FIG. 3, there may exist another film between the magnetic layer MF and the magnetic pinned layers HL1 and HL2.

As shown in FIG. 5, the magnetoresistance effect element MR has the magnetic layer MF provided so as to extend in the direction x, the tunnel barrier layer TB extending in the direction x, and the magnetic layer MFI provided adjacent onto the tunnel barrier layer TB and on the side opposite to the magnetic layer MF. The magnetic layer MF has, adjacent to the lower surface at both ends thereof, the magnetic pinned layers HL1 and HL2.

The magnetic layer MF, the magnetic layer MFI, the magnetic pinned layers HL1 and HL2 are each made of a ferromagnetic material. In FIG. 7, a white arrow shows the magnetization direction of each of the magnetic layer MF, the magnetic layer MFI, and the magnetic pinned layers HL1 and HL2. As shown in FIG. 7, the magnetization direction of each of the magnetic layer MF, the magnetic layer MFI, and the magnetic pinned layers HL1 and HL2 is substantially parallel to the z axis. To achieve such a magnetization direction, the magnetic layer MF, the magnetic layer MFI, and the magnetic pinned layer HL1 and HL2 are preferably made of a material or stacked film having perpendicular magnetization. The stacked film may be a film obtained by stacking ferromagnetic materials or a film obtained by stacking a ferromagnetic material and a non-magnetic material.

As shown in FIG. 6, the magnetic layer MF is equipped with magnetic pinned portions FP1 and FP2, a magnetic domain wall displacement portion WM, and magnetic domain wall pinning sites MW1 and MW2. As shown in FIG. 7, the magnetic pinned portion FP1 is one of the end portions of the magnetic layer MF in the x-axis direction, while the magnetic pinned portion FP2 is the other end portion of the magnetic layer MF in the x-axis direction. The magnetic domain wall displacement portion WM is the center portion of the magnetic layer MF in the x-axis direction. The magnetic domain wall displacement portion WM and the magnetic pinned portion FP1 have therebetween a magnetic domain wall pinning site MW1, while the magnetic domain wall displacement portion WM and the magnetic pinned portion FP2 have therebetween a magnetic domain wall pinning site MW2.

The magnetization direction of the magnetic layer (the magnetic pinned layer) MFI and the magnetic pinned layers HL1, and HL2 does not change because it is fixed, but the magnetization direction of the magnetic layer (magnetic free layer) MF can be reversed in the z-axis direction, more specifically, between a +z direction and a −z direction. The magnetic layer MFI is provided so as to overlap, in plan view, with at least a portion of the magnetic domain wall displacement portion WM. The magnetic pinned layers HL1 and HL2 are provided adjacent to the magnetic pinned portions FP1 and FP2 in the z-axis direction. The magnetization direction of the magnetic pinned portions FP1 and FP2 are therefore fixed in a substantially antiparallel direction to each other. The magnetization of the magnetic domain wall displacement portion WM can be reversed between the +z direction and the −z direction

At this time, a magnetic domain wall is formed on either one of the magnetic domain wall pinning site MW1 and the magnetic domain wall pinning site MW2, depending on the magnetization direction of the magnetic pinned portions FP1 and FP2 and the magnetic domain wall displacement portion WM. The magnetic domain wall pinning sites MW1 and MW2 have a function of anchoring the magnetic domain wall stably when no magnetic field is applied to this system or when no current flows therethrough. It has been revealed by micromagnetic calculation that in the structure shown in FIGS. 5 to 7, the magnetic domain wall can be pinned naturally even without providing a special structure as the magnetic domain wall pinning sites MW1 and MW2. The magnetic domain wall pinning sites MW1 and MW2 may have a device for intentionally increasing the pinning potential.

The magnetic pinned portions FP1 and FP2 and the magnetic layer MFI are electrically coupled to respectively different outside wirings. The magnetic pinned portions FP1 and FP2 may be electrically coupled to outside wirings via the magnetic pinned layers HL1 and HL2. This means that the magnetoresistance effect element MR is a three-terminal element.

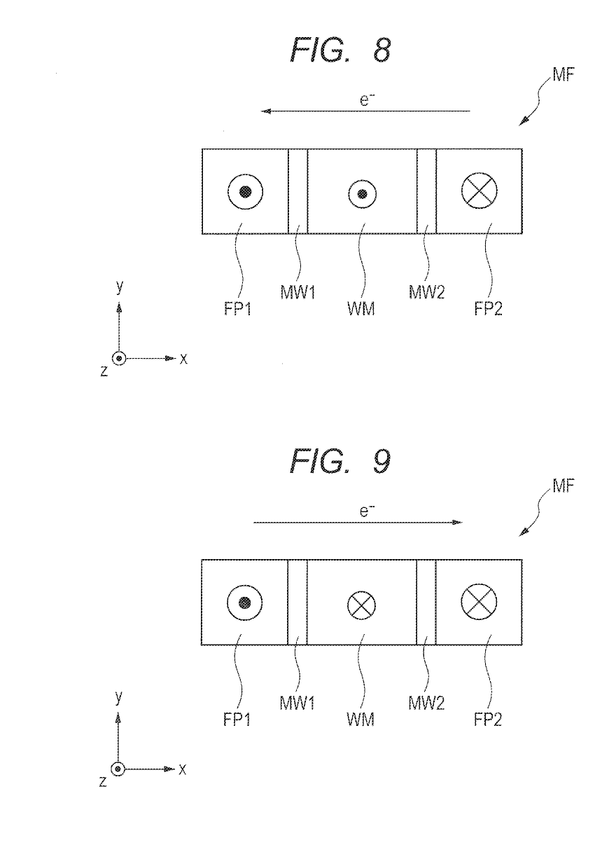

Next, a method of writing data in the magnetoresistance effect element MR will be described referring to FIGS. 8 and 9. FIGS. 8 and 9 are plan views schematically showing two states that the magnetoresistance effect element MR can take, that is, state “0” (refer to FIG. 8) and state “1” (refer to FIG. 9). The state “0” means that data “0” is written in the magnetoresistance effect element MR and the state “1” means that data “1” is written in the magnetoresistance effect element MR.

The following description will be made supposing that the magnetization of the magnetic pinned portion FP1 is fixed to the +z direction and the magnetization of the magnetic pinned portion FP2 is fixed to the −z direction. In addition, in the following description, it is defined that in the state “0” shown in FIG. 8, the magnetic domain wall displacement portion WM is magnetized in the +z direction and in the state “1” shown in FIG. 9, the magnetic domain wall displacement portion WM is magnetized in the −z direction. The respective magnetization directions of the the magnetic pinned portions FP1 and FP2 are not limited to the above-described direction and they may be substantially antiparallel to each other, that is, opposite to each other. It is needless to say that the definition on the relation between the data and the magnetization direction of the magnetic domain wall displacement portion WM is not limited to that described above.

Under the above-described magnetized state, the magnetic domain wall is formed on the magnetic domain wall pinning site MW2 in the state “0” and the magnetic domain wall is formed on the magnetic domain wall pinning site MW1 in the state “1”. In the present embodiment, by changing the direction of a current flowing through the magnetic layer MF, the magnetic domain wall is moved between the magnetic domain wall pinning sites MW1 and MW2 and thereby, desired data are written in the magnetoresistance effect element MR.

For example, when the magnetoresistance effect element MR is in the state “0” in FIG. 8 and a current flows in the +x direction, in other words, conduction electrons flow in the −x direction, a spin transfer torque by the conduction electrons is applied to the magnetic domain wall present at the magnetic domain wall pinning site MW2. Then, the magnetic wall moves in a direction similar to that of the conduction electrons and reaches the magnetic domain wall pinning site MW1. When the magnetoresistance effect element MR is in the state “1” in FIG. 9 and a current flows in the −x direction, in other words, conduction electrons flow in the +x direction, a spin transfer torque by the conduction electrons is applied to the magnetic domain wall present at the magnetic domain wall pinning site MW1. Then, the magnetic wall moves in a direction similar to that of the conduction electrons and reaches the magnetic domain wall pinning site MW2. In such a manner, writing from the state “0” to the state “1” and from the state “1” to the state “0” can be achieved.

When the magnetoresistance effect element MR is in the state “0” shown in FIG. 8 and a current is supplied in the −x direction, that is, data “0” is written, the magnetic domain wall tries to move in the +x direction, but magnetic domain wall displacement does not occur if the magnetization of the magnetic pinned portions FP2 is fixed with adequate intensity. This means the possibility of overwrite operation (write operation without reversing the magnetization direction). Even when the magnetization of the magnetic pinned portion FP2 is reversed in the +z direction due to the magnetic domain wall displacement, the overwrite operation as described above can be carried out if the element is equipped with a means for restoring the original state, that is, a means for returning the magnetization to the −z direction when the flow of the current stops. As this means, the magnetic interaction with the magnetic pinned layers HL1 and HL2 can be used.

Next, a method of reading data from the magnetoresistance effect element MR of the present embodiment will be described referring to FIG. 7. In the present embodiment, data are stored, depending on the magnetization direction of the magnetic domain wall displacement portion WM and the magnetic domain wall displacement portion WM is coupled to magnetic layer MFI via the tunnel barrier layer TB. A magnetoresistance effect is used for reading data from the magnetoresistance effect element MR. Due to the magnetoresistance effect, the resistance value of the magnetic tunnel junction (or spin valve) comprised of the magnetic layer MF, the tunnel barrier layer TB, and the magnetic layer MFI differs with the magnetization direction of the magnetic domain wall displacement portion WM. Data can therefore be read by applying a current between the magnetic layer MF and the magnetic layer MFI.

For example, when the magnetization direction of the magnetic domain wall displacement portion WM in the magnetic layer MF and the magnetization direction of the magnetic layer MFI are the same, a low resistance state is achieved. When the magnetization direction of the magnetic domain wall displacement portion WM and the magnetization direction of the magnetic layer MFI are opposite to each other, a high resistance state is achieved.

### <Advantage of Semiconductor Device>

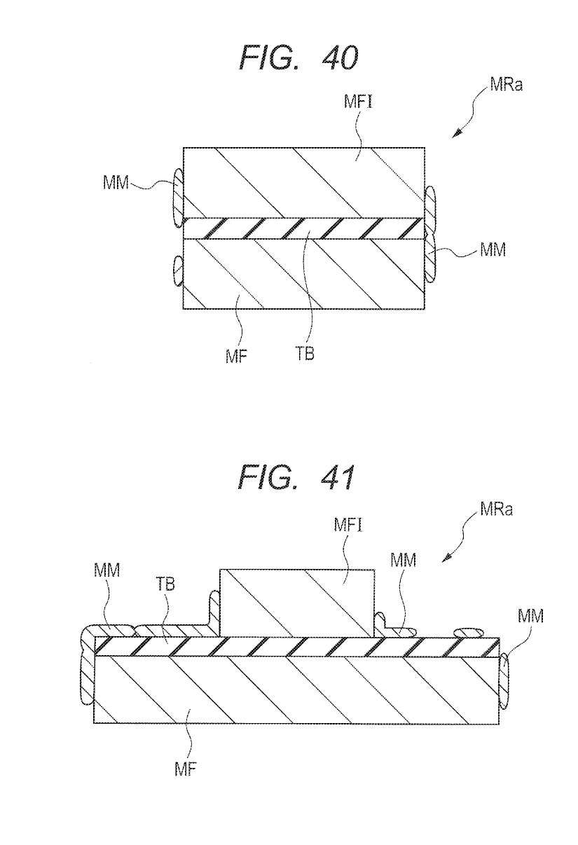

The advantage of the semiconductor device of the present embodiment will hereinafter be described referring to FIGS. 40 and 41 that show a semiconductor device of Comparative Example. FIGS. 40 and 41 are cross-sectional views showing a magnetoresistance effect element MRa of Comparative Example and the other structures are omitted from these drawings. The cross-section shown in FIG. 40 and the cross-section shown in FIG. 41 are cross-sections that perpendicularly intersect with each other.

The magnetoresistance effect element MRa of Comparative Example shown in FIGS. 40 and 41 has, similar to the magnetoresistance effect element MR of the present embodiment shown in FIGS. 1 and 2, a stacked structure comprised of a magnetic layer MF, a tunnel barrier layer TB, and a magnetic layer MFI. A large difference between the magnetoresistance effect element MRa of Comparative Example and the magnetoresistance effect element MR of the present embodiment is that in Comparative Example, the respective side walls of the magnetic layer MF and the magnetic layer MFI are not covered with an insulating film such as an oxide film.

In fact, the magnetoresistance effect element MRa of Comparative Example is covered with an insulating film IF10 and an interlayer insulating film IL5 (refer to FIG. 3), but the respective side walls of the magnetic layer MF and MFI are not covered with oxide films OL1 and OL2 (refer to FIGS. 1 and 2). As shown in FIGS. 40 and 41, a metal deposit MM is attached onto the surface of the magnetoresistance effect element MRa. The metal deposit MM thus attached is presumed to be in film form or in the form of a plurality of islands. In this example, the metal deposit MM is contiguous to the respective side walls of the magnetic layers MF and MFI and contiguous to the upper surface of the tunnel barrier layer TB on the side of the magnetic layer MFI. When the tunnel barrier layer TB, unlike the magnetic layer MF, does not extend, the metal deposit MM attaches also to the upper surface of the magnetic layer MF exposed from the tunnel barrier layer TB.

The metal deposit MM is a conductor substance generated in a step, among manufacturing steps of a semiconductor device, of processing the stacked film by dry etching (anisotropically dry etching) and thereby patterning the magnetic layer MF, the tunnel barrier layer TB, and the magnetic layer MFI.

Described specifically, when the conductor film provided for the formation of the magnetic layers MF and MFI is processed by partial removal in the above step, metal particles configuring the conductor film of the removed portion return and attach to the surface of the structures on the semiconductor substrate to form the metal deposit MM. In other words, the metal deposit MM is a conductor substance that configures a portion of the magnetic layers MF or MFI and after anisotropic etching, attaches to the surface of the magnetoresistance effect element formed by the anisotropic etching.

This means that the metal deposit MM contains a metal similar to the metal configuring the magnetic layers MF and MFI. For example, when the magnetic layers MF and MFI are made of CoFeB, the metal deposit MM is made of Co, Fe, and B, or a compound thereof. Attachment of such a metal deposit MM onto the side wall of the magnetoresistance effect element MRa or the like may cause such a problem that conduction occurs between the magnetic layer MF and the magnetic layer MFI via the metal deposit MM comprised of a conductor such as Co or Fe. In this case, a leakage current between the magnetic layers MF and MFI increases. It is however to be noted that a deposit comprised of B (boron) has low conductivity so that it is unlikely to become a cause of a leakage current.

When a leakage current flows or a short-circuit occurs between the magnetic layers MF and MFI, the magnetic property of the magnetic layer MF cannot be changed normally as described referring to FIGS. 7 and 8 and therefore, write operation or read operation of data cannot be performed normally. As a result, the semiconductor device thus obtained has deteriorated reliability.

In the semiconductor device of the present embodiment, on the other hand, respective exposed surfaces of the magnetic layers MF and MFI are oxidized by subjecting the magnetoresistance effect element MR including the magnetic layers MF and MFI formed by the above processing to plasma treatment as shown in FIGS. 1 and 2. Since oxide films OL1 and OL2 that cover their respective exposed surfaces of the magnetic layers MF and MFI are formed, even when the metal deposit MM (refer to FIGS. 40 and 41) remain in the vicinity of the magnetic layer MFI, the oxide films OL1 and OL2 can protect the magnetic layers MF and MFI from the metal deposit MM.

Occurrence of a leakage current and short-circuit due to the metal deposit MM can be prevented so that the write operation and read operation can be performed normally by applying a desired current to the magnetoresistance effect element MR. The semiconductor device thus obtained can therefore have improved reliability. As will be described later referring to FIGS. 20 to 26, the metal deposit MM can be sublimed and removed by the above-described plasma treatment.

### <Manufacturing Method of Semiconductor Device>

Described next is prevention of occurrence of a leakage current by forming a magnetoresistance effect element configuring MRAM and carrying out plasma treatment in a gas atmosphere containing carbon and oxygen to form a carbonyl group, and thereby subliming a substance containing the carbonyl group (carbonyl compound) and forming an oxide film on the side wall of the magnetoresistance effect element by the plasma treatment.

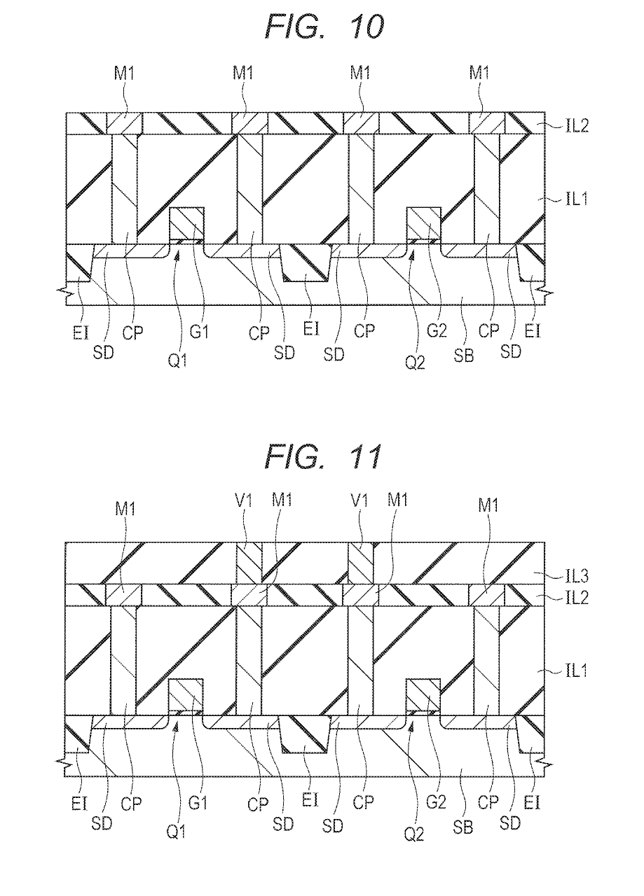

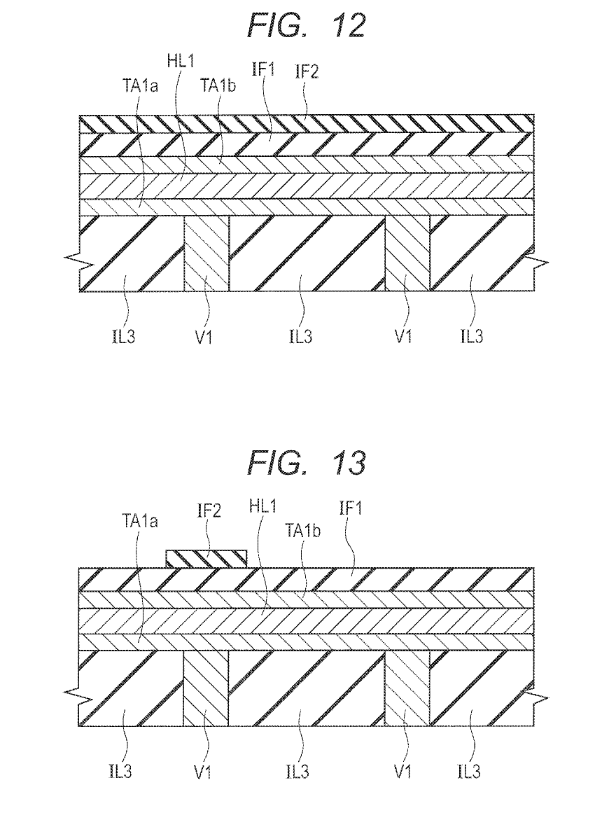

First, a method of manufacturing the semiconductor device of the present embodiment will be described referring to FIGS. 10 to 30. FIGS. 10 to 30 are cross-sectional views of the semiconductor device of the present embodiment during manufacturing steps thereof. The main characteristic of the present embodiment however resides in the method of manufacturing a magnetoresistance effect element so that a detailed description on the structure of a transistor which is a selective element of the magnetoresistance effect transistor will be omitted. FIGS. 12 to 29 show only the enlarged cross-section in the vicinity of a formation region of the magnetoresistance effect element in order to facilitate understanding of them. More specifically, FIGS. 12 to 29 show the cross-section of a region above a first wiring layer.

First as shown in FIG. 10, a semiconductor substrate SB made of, for example, single crystal silicon is provided. A trench is formed in the main surface of the semiconductor substrate SB and an element isolation region EI made mainly of, for example, a silicon oxide film is formed in the trench. In the main surface of the semiconductor substrate on the side of the element isolation region EI, that is, in an active region, an N type MOS transistor Q1 and an N type MOS transistor Q2 are then formed. The MOS transistors Q1 and Q2 are separated from each other by the element isolation region EI. The MOS transistors Q1 and Q2 may be a P type MOSFET (metal oxide semiconductor field effect transistor).

After formation of an interlayer insulating film IL1 made of, for example, a silicon oxide film on the semiconductor substrate SB, a plurality of contact plugs CP penetrating through the interlayer insulating film IL1 is then formed. The upper surface of the contact plugs CP and the upper surface of the interlayer insulating film IL1 are planarized by polishing such as CMP (chemical mechanical polishing). The contact plugs CP are coupled, respectively, to source and drain regions which the MOS transistors Q1 and Q2 each have.

After formation of an interlayer insulating film IL2 made of, for example, a silicon oxide film on the interlayer insulating film IL1, a plurality of wirings M1 penetrating through the interlayer insulating film IL2 is then formed. The upper surface of the wirings M1 and the upper surface of the interlayer insulating film IL2 are planarized by polishing such as CMP. The wirings M1 are then coupled to the upper surface of the contact plugs CP, respectively. Thus, a first wiring layer including the interlayer insulating film IL2 and the plurality of wirings M1 is formed.

Next, as shown in FIG. 11, an interlayer insulating film IL3 made of, for example, a silicon oxide film is formed on the first wiring layer using, for example, CVD (chemical vapor deposition). By photolithography and dry etching, a via hole from which the upper surface of some of the wirings M1 is exposed is formed in the interlayer insulating film IL3. The wirings M1 exposed here are the wirings M1 electrically coupled to one of the source and drain regions of the MOS transistor Q1 and one of the source and drain regions of the MOS transistor Q2, respectively.

Subsequently, a conductor film made mainly of copper (Cu) is formed on each of the interlayer insulating films IL2 and IL3 and the wirings M1 by sputtering and plating to fill the via holes therewith. The conductor film on the interlayer insulating film IL2 is then removed by CMP to expose the upper surface of the interlayer insulating film IL2. Thus, a via V1 made of the conductor film is formed in each of the via holes.

Next, as shown in FIG. 12, a conductor film TA1a, a magnetic pinned layer HL1, and a conductor film TA1b are formed successively on the interlayer insulating film IL3 and the via V1, for example, by sputtering. The conductor films TA1a and TA1b are conductor films containing, for example, Ta (tantalum) and the magnetic pinned layer HL1 is a magnetic material layer containing, for example, Co (cobalt). Subsequently, an insulating film IF1 made of a silicon nitride film and an insulating film IF2 made of a silicon oxide film are formed successively using, for example, CVD on the conductor film TA1b.

Next, as shown in FIG. 13, the upper surface of the insulating film IF1 is partially exposed by processing the insulating film IF2 by photolithography and dry etching. In this drawing, the insulating film IF2 is left immediately on one of the two vias V1 thus formed and the insulating film IF2 in the other region is removed.

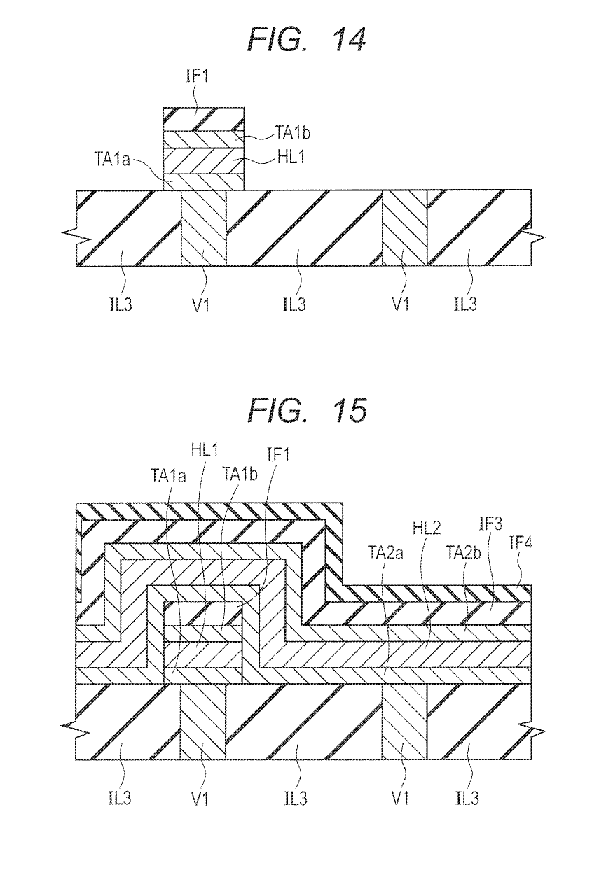

Next, as shown in FIG. 14, the insulating film IF1, the conductor film TA1b, the magnetic pinned layer HL1, and the conductor film TA1a are patterned by dry etching with the insulating film IF2 as a hard mask. A stacked film comprised of the conductor film TA1a, the magnetic pinned layer HL1, the conductor film TA1b, and the insulating film IF1 covers the upper surface of one of the two vias V1. By this patterning, the upper surface of the interlayer insulating film IL3 and the upper surface of the other via V1 are exposed. Here, the description is made, while regarding the insulating film IF2 as a film to be removed.

Next, as shown in FIG. 15, a conductor film TA2a, a magnetic pinned layer HL2, and a conductor film TA2b are formed successively on the interlayer insulating film IL3, the via V1, and the stacked film, for example, by sputtering. The conductor films TA2a and TA2b are conductive films containing, for example, Ta (tantalum) and the magnetic pinned layer HL2 is a magnetic material layer containing, for example, Co (cobalt). An insulating film IF3 made of a silicon nitride film and an insulating film IF4 made of a silicon oxide film are then formed successively on the conductor film TA2b, for example, by CVD.

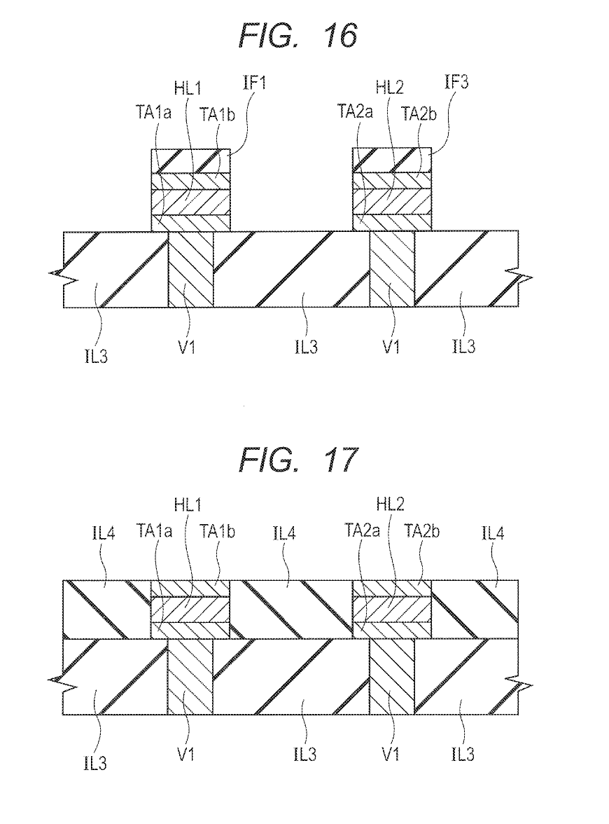

Next, as shown in FIG. 16, steps almost similar to those described referring to FIGS. 13 and 14 are carried out to form a pattern that covers the upper surface of the via V1 exposed after the step described referring to FIG. 14 and is comprised of a stacked film including the conductor film TA2a, the magnetic pinned layer HL2, the conductor film TA2b, and the insulating film IF3.

Described specifically, the insulating film IF4 is processed using photolithography and dry etching to expose a portion of the upper surface of the insulating film IF3. Here, the insulating film IF4 is left right above the via V1, of the two vias V1, not covered with the conductor film TA1a and the insulating film IF4 in the other region is removed. With the insulating film IF4 as a hard mask, dry etching is then performed to pattern the insulating film IF3, the conductor film TA2b, the magnetic pinned layer HL2, and the conductor film TA2a. By this patterning, the interlayer insulating film IL3 and the stacked film comprised of the conductor film TA1a, the magnetic pinned layer HL1, the conductor film TA1b, and the insulating film IF1 are exposed. Here, the description is made while regarding the insulating film IF4 as a film to be removed.

Thus, a stacked film including the conductor film TA1a, the magnetic pinned layer HL1, the conductor film TA1b, and the insulating film IF1 right above one of the two vias V1 and a stacked film including the conductor film TA2a, the magnetic pinned layer HL2, the conductor film TA2b, and the insulating film IF3 right above the other via V1 are formed. These stacked films are separated from each other.

As shown in FIG. 17, an insulating film made of, for example, a silicon nitride film is then formed using, for example, CVD on each of the two stacked films and the interlayer insulating film IL3. The upper surface of the insulating film is then polished using, for example, CMP. During this polishing, the insulating films IF1 and IF3 are also removed by polishing. The respective upper surfaces of the conductor films TA1b and TA2b are thereby exposed to form an interlayer insulating film IL4 made of the insulating film. The upper surface of the interlayer insulating film IL4 and the respective upper surfaces of the conductor films TA1b and TA2b are planarized to have the same surface level.

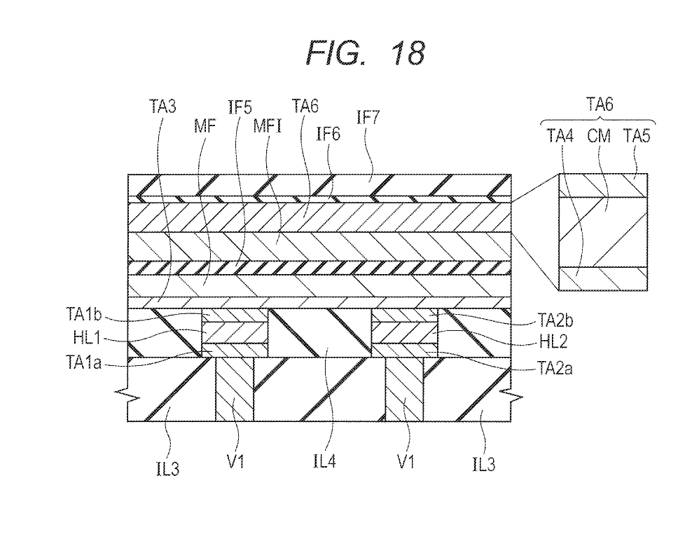

Next, as shown in FIG. 18, a conductor film TA3, a magnetic layer (magnetic free layer) MF, an insulating layer (oxidized magnetic layer) IF5, a magnetic layer (magnetic pinned layer) MFI, a conductor film TA6, and insulating films IF6 and IF7 are formed successively on each of the interlayer insulating film IL4 and the conductor films TA1b and TA2b by using, for example, sputtering and CVD. The conductor film TA3 is a conductor film containing, for example, Ta (tantalum). The magnetic layers MF and MFI are each made of, for example, CoFeB, that is, an alloy containing Co (cobalt), Fe (iron), and B (boron). The insulating layer IF5 is an oxidized magnetic layer made of, for example, MgO (magnesium oxide) or AlOx (0<x<1) (aluminum oxide).

The conductor film TA6 has, as shown in the enlarged drawing on the right side, a stacked structure including conductor films TA4, CM, and TA5 formed successively on the magnetic layer MFI. The conductor films TA3 and TA4 are each a conductor film containing, for example, Ta (tantalum). The conductor film CM is a magnetic material layer containing, for example, Co (cobalt). The insulating film IF6 is made of, for example, a silicon nitride film and the insulating film IF7 is made of, for example, a silicon oxide film.

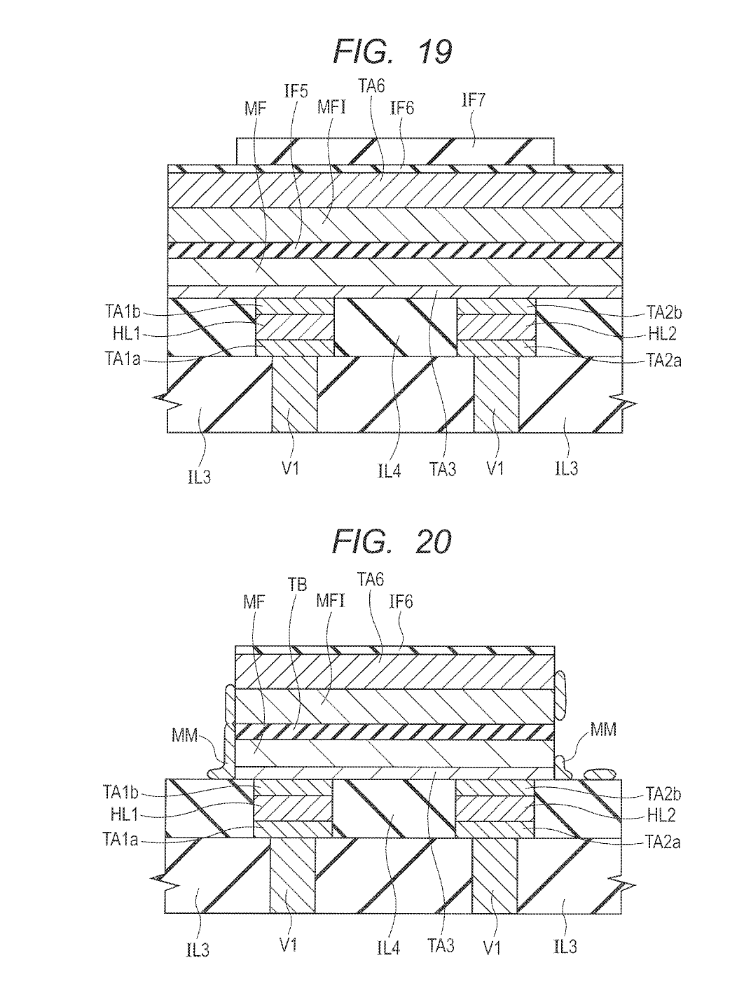

Next, as shown in FIG. 19, the insulating film IF7 is processed by photolithography and dry etching to expose a portion of the upper surface of the insulating film IF6. The pattern of the insulating film IF7 thus formed by this processing overlaps, in plan view, with both the magnetic pinned layer HL1 and the magnetic pinned layer HL2.

Next, as shown in FIG. 20, the insulating film IF6, the conductor film TA6, the magnetic layer MFI, the insulating layer IF5, the magnetic layer MF, and the conductor film TA3 are processed by dry etching (anisotropic etching) with the insulating film IF7 as a hard mask. Dry etching performed here is plasma etching. The plasma etching is performed with a gas such as methanol (CH₃OH), ethanol (C₃H₆O), argon (Ar) or chlorine (Cl). By this etching, a portion of the upper surface of the interlayer insulating film IL4 is exposed, and in addition, a tunnel barrier layer TB comprised of the insulating layer IF5 is formed. The present etching step is performed to form a final pattern of the magnetic layer MF and the tunnel barrier layer TB. The description here is made while regarding the insulating film IF7 as a film to be removed.

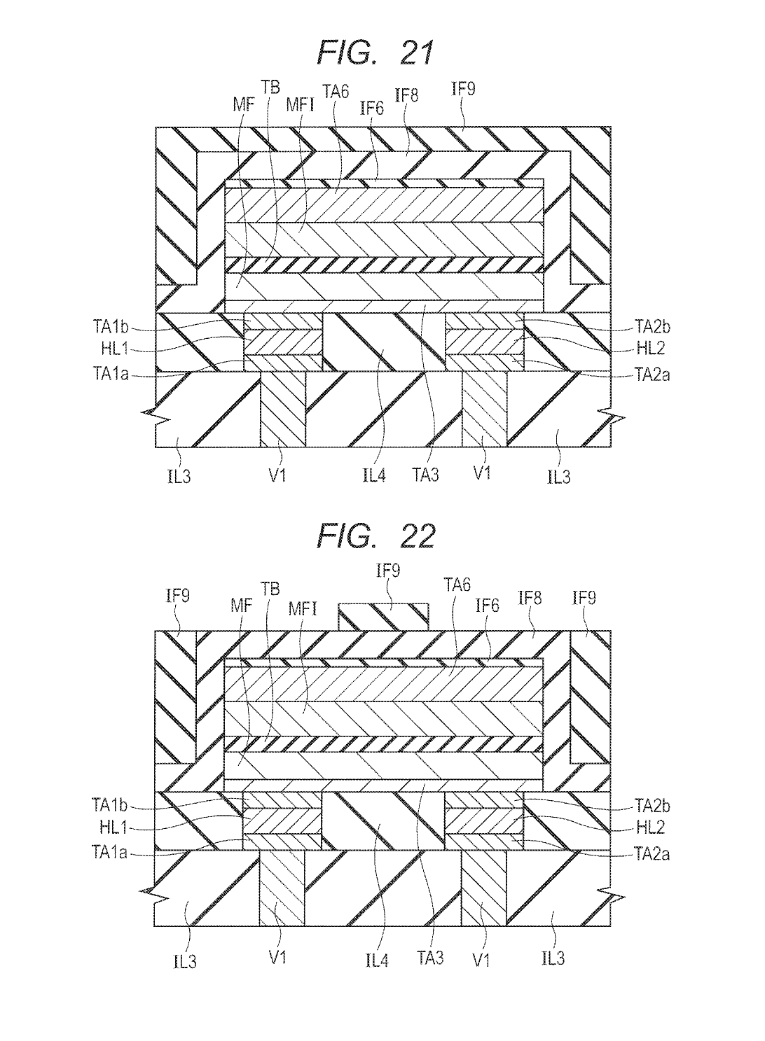

A portion of each of the magnetic layers MF and MFI is removed by this dry etching, but metal particles configuring the magnetic layers MF and MFI thus removed become a reaction product. A portion of the reaction product is discharged from a plasma apparatus (parallel plate plasma apparatus) in which the dry etching (plasma etching) is performed but the other portion remains in the plasma apparatus. The reaction product that has remained in the plasma apparatus may attach to the upper surface of the interlayer insulating film IL4, the side wall of the magnetic layer MF, and the side wall of the MFI exposed by the above processing. In the drawing, such a reaction product that has attached to the side wall of the magnetic layer MF and the side wall of the MFI is shown as a metal deposit MM. To facilitate understanding, however, the metal deposit MM is omitted from FIGS. 21 to 23.

For example, when the magnetic layers MF and MFI are made of CoFeB, the metal deposit MM is made of Co, Fe, and B, or a compound thereof.

Next, as shown in FIG. 21, insulating films IF8 and IF9 are formed successively on the interlayer insulating film IL4, for example, by CVD to cover the upper surface of the interlayer insulating film IL4 and the stacked film including the magnetic layers MF and MFI on the interlayer insulating film IL4. The upper surface of the insulating film IF9 is then polished, for example, by CMP. In this polishing step, the upper surface of the insulating film IF8 is not exposed. Although not illustrated here, the metal deposit MM (refer to FIG. 20) stays partially between the insulating film IF8 and the respective side walls of the magnetic layer MF and MFI.

Next, as shown in FIG. 22, the insulating film IF9 is processed using photolithography and dry etching to expose a portion of the upper surface of the insulating film IF8. The insulating film IF9 is left right above a region between the magnetic pinned layers HL1 and HL2 and the entirety of the insulating film IF8 on the side of the insulating film IF9 right above the region is exposed. This means that the insulating film IF9 right above each of the magnetic pinned layers HL1 and HL2 is removed. The insulating film IF9 remains on the side of the insulating film IF8 that covers the stacked film including the magnetic layers MF and MFI on the interlayer insulating film IL4. The insulating film IF9 therefore remains on the side of the side wall of the stacked film via the insulating film IF8.

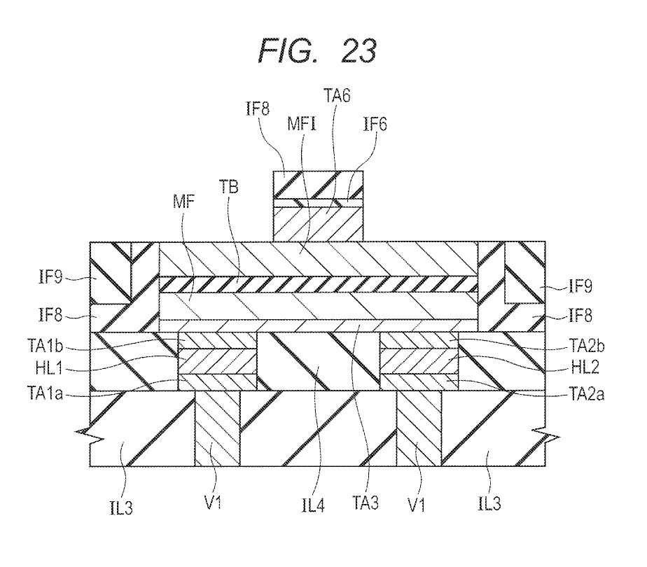

Next, as shown in FIG. 23, dry etching is performed with the insulating film IF9 as a hard mask to process the insulating film IF8 and the conductor film TA6. This etching exposes the upper surface of the magnetic layer MFI right above each of the magnetic pinned layers HL1 and HL2. The insulating film IF9 sometimes remains on the side of the magnetic layer MFI via the insulating film IF8. Here, the description is made while regarding the insulating film IF9 right above the magnetic layer MFI as a film to be removed by etching.

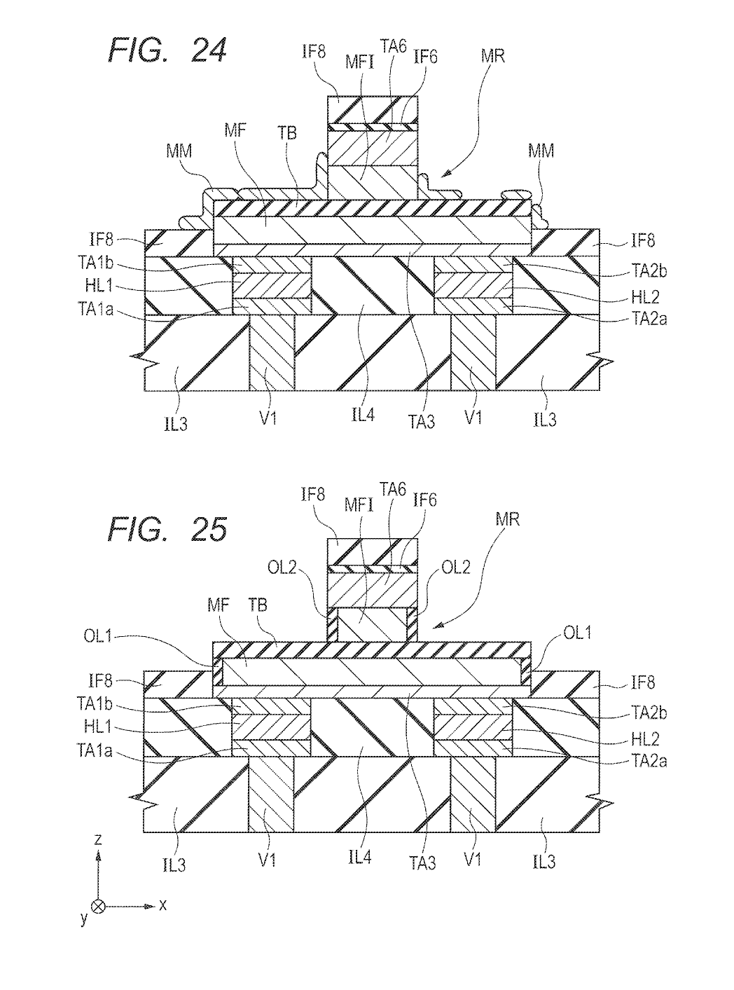

Next, as shown in FIG. 24, with the insulating film IF8 as a hard mask, dry etching (plasma etching, anisotropic etching) is performed in a plasma apparatus to remove a portion of the magnetic layer MFI and thereby expose the upper surface of the tunnel barrier layer TB. The plasma etching is performed using a gas such as methanol (CH₃OH), ethanol (C₃H₆O), argon (Ar), or chlorine (Cl).

By the above dry etching, the insulating film IF9 and a portion of the insulating film IF8 on the side of the stacked film including the magnetic layers MF and MFI and the tunnel barrier layer TB are removed. The insulating film IF8 on the side of the stacked film including the magnetic layers MF and MFI and the tunnel barrier layer TB is sometimes removed completely. The upper surface of the magnetic layer MF may be exposed by removing a portion of the tunnel barrier layer TB by this etching. Here, the description is made supposing that the height of the upper surface of the insulating film IF8 becomes lower than the height of the upper surface of the tunnel barrier layer TB.

During this step, the metal deposit MM formed on the side wall of the magnetic layer MF is exposed from the insulating film IF8. In addition, the present etching for processing the magnetic layer MFI forms another metal deposit MM. This means that in a region from which the magnetic layer MFI has been removed, a metal deposit MM made of metal particles configuring the magnetic layer MFI attaches to the side wall of the magnetic layer MFI and the upper surface of the tunnel barrier layer TB on the side of the magnetic layer MFI. When the magnetic layer MF is not covered with the tunnel barrier TB on the side of the magnetic layer MFI, the metal deposit MM attaches also to the upper surface of the magnetic layer MF. The metal deposit MM formed in this step is also made of Co, Fe, and B, or a compound thereof.

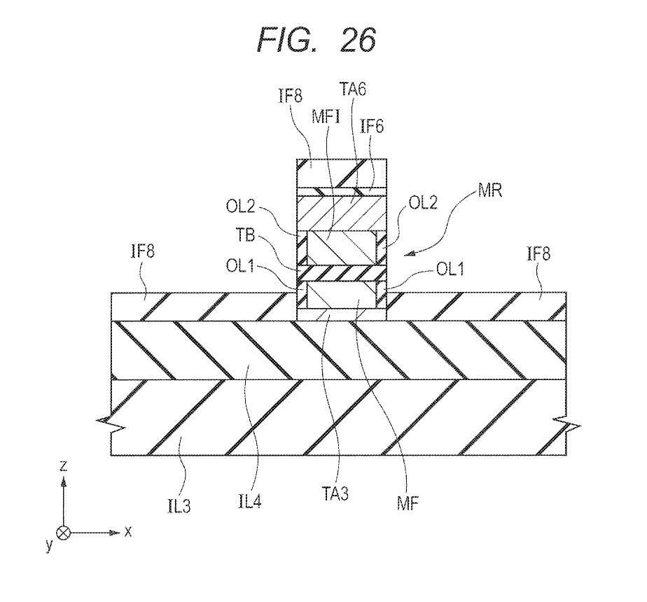

Next, as shown in FIGS. 25 and 26, the dry etching step using the plasma apparatus is followed by plasma treatment in the plasma apparatus. This treatment sublimes and removes the metal deposit MM. In addition, the side wall of the magnetic layer MF is oxidized to form an oxide film OL1 that covers the side wall of the magnetic layer MF, while the side wall of the magnetic layer MFI is oxidized to form an oxide film OL2 that covers the side wall of the magnetic layer MFI. Further, the metal deposit MM that has remained without being sublimed is oxidized. FIG. 26 shows a cross-section along the backward direction (y-axis direction) and the z-axis direction of FIG. 25 and a cross-section of a position including the magnetoresistance effect element MR.

More specifically, the plasma treatment is performed under the following conditions. For the plasma treatment, a parallel plate plasma apparatus is used. In the present plasma treatment, the plasma apparatus is supplied with a gas containing C (carbon) and O (oxygen). As the gas containing C (carbon) and O (oxygen), a gas containing either one or both of a CO (carbon monoxide) gas and a CO₂ (carbon dioxide) gas is used. In addition to this gas, an inert gas such as Ar (argon) gas or He (helium) gas may be supplied for activation of plasma.

The flow rate of the gas supplied in the present plasma treatment is from 1 to 15 L/min. The above-described gas containing C (carbon) and O (oxygen) amounts to from 70 to 100% of the total flow rate of the gas supplied to the etching apparatus. The pressure in the plasma etching apparatus is set at from 1 to 5 Torr. The power of a radio frequency (RF) power source supplied to the plasma apparatus for generating plasma is from 500 to 1500 W.

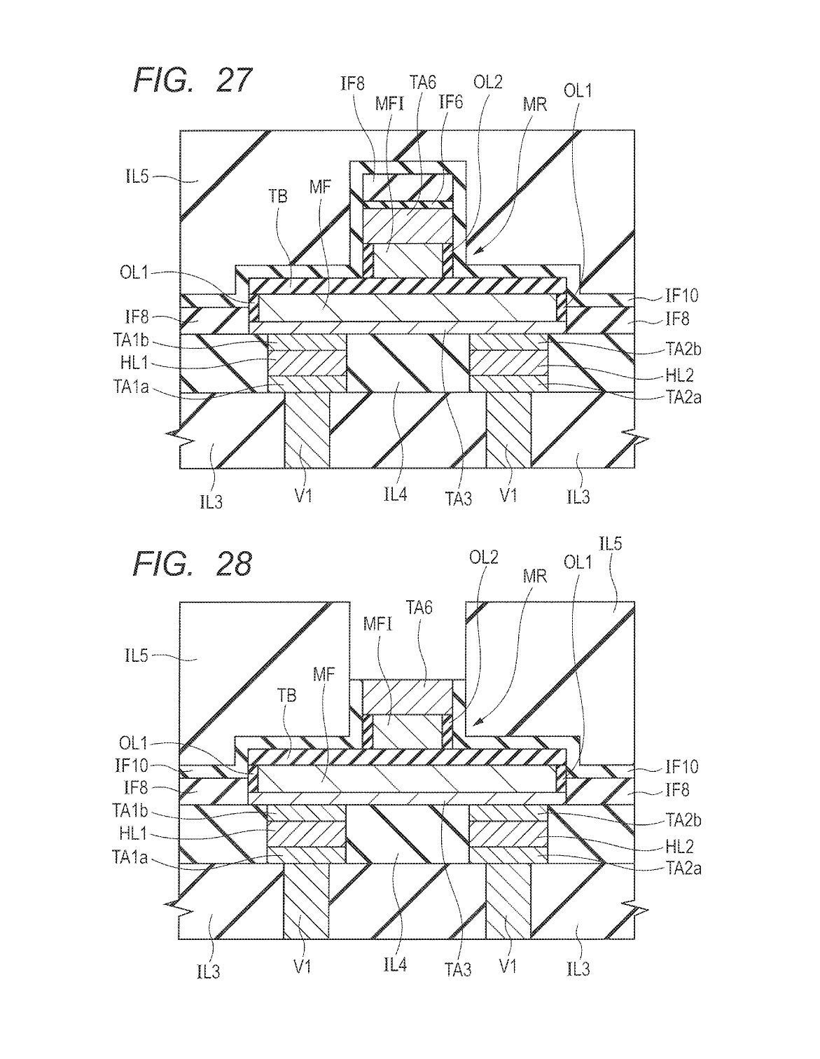

The temperature in the apparatus is set at 104° C. or more and in this step, it is adjusted to from 200 to 300° C. More specifically, it is set at 250° C. The temperature in the apparatus in the plasma treatment is set at from 200 to 300° C. in order to carry out, in the same apparatus, a step of forming a silicon nitride film which will be described later referring to FIG. 27. By carrying out film formation at the above-described temperature, a silicon nitride thus formed has an enhanced quality.

With the plasma of the plasma treatment performed as described above using a carbon oxide gas (for example, a Cox gas such as Co gas or CO₂ gas), the metal deposit MM made of Co, Fe, or the like forms a carbonyl group. This means that the metal deposit mM reacts with the carbon oxide gas to form a carbonyl group. The carbonyl compound containing the carbonyl group is made of, for example, a Co₂(CO)₈ or Fe(CO)₅.

The carbonyl compound (for example, Co₂(CO)₈) formed by the plasma treatment of the metal deposit MM containing Co sublimes at 52° C. The carbonyl compound (for example, Fe(CO)₅) formed by the plasma treatment of the metal deposit MM containing Fe sublimes at 103° C. The carbonyl compound derived from the metal deposit MM is therefore removed here by the plasma treatment at a temperature of 104° C. or more. This means that the metal deposit MM on the semiconductor substrate including the surface of the magnetoresistance effect element MR is removed. The metal deposit MM is therefore not shown in FIGS. 25 and 26.

In addition, by the plasma treatment in this step, the respective surfaces exposed from the magnetic layers MF and MFI configuring the magnetoresistance effect element MR are oxidized to form oxide films OL1 and OL2. The oxide film OL1 contains an oxide of the composition of the magnetic layer MF and the oxide film OL2 contains an oxide of the composition of the magnetic layer MFI. Although not illustrated here, even when the metal deposit MM is not sublimed by the above-described plasma treatment, the remaining metal deposit MM is oxidized. The oxide films OL1 and OL2 and the oxide of the metal deposit MM are each made of, for example, CoO (cobalt oxide), FeO (iron oxide), Fe₂O₃ (iron trioxide) or B₂O₃ (boron oxide, diboron trioxide).

Simultaneously with the etching step described referring to FIG. 24, the plasma treatment may be performed by supplying the above-described Cox gas to the plasma apparatus. In this case, a magnetoresistance effect element MR is formed by members including the magnetic layer MFI processed by this etching, the metal deposit MM is sublimed as a carbonyl compound, and the oxide films OL1 and OL2 are formed on the side wall of the magnetic layers MF and MFI, respectively.

When on the side of the magnetic layer MFI, the magnetic layer MF is not covered by the tunnel barrier layer TB, the metal deposit MM that has attached to the upper surface of the magnetic layer MF sublimes as a carbonyl compound, and the oxide film OL1 is formed also on the upper surface of the magnetic layer MF exposed from the tunnel barrier layer TB. On the other hand, when the tunnel barrier layer TB is left on the upper surface of the magnetic layer MF as shown in FIG. 25, even if a portion of the metal deposit MM having conductivity remains, generation of a leakage current due to the metal deposit MM can be prevented more easily. This advantage is brought about because a conduction path from the side wall of the magnetic layer MF to the side wall of the magnetic layer MFI becomes longer.

Next, as shown in FIG. 27, the plasma apparatus used for the plasma treatment is used continuously and an insulating film IF10 made of, for example, a silicon nitride film is formed on the magnetoresistance effect element MR and the insulating film IF8 by plasma CVD. An interlayer insulating film IL5 is then formed on the insulating film IF10 by using, for example, CVD. The interlayer insulating film IL5 is made of, for example, a silicon oxide film. The upper surface of the interlayer insulating film IL5 is then planarized by polishing, for example, by CVD. By this polishing, the upper surface of the insulating film IF10 is not exposed.

Next, a via hole penetrating through the interlayer insulating film IL5 and the insulating films IF10, IF8, and IF6 is formed using photolithography and dry etching. This drawing shows a cross-section in the case where the via hole on the conductor film TA6 has a width almost equal to that of the conductor film TA6 so that it includes neither the insulating film IF6 nor the IF8 on the conductor film TA6. The width of the via hole may however be smaller than that of the conductor film TA6.

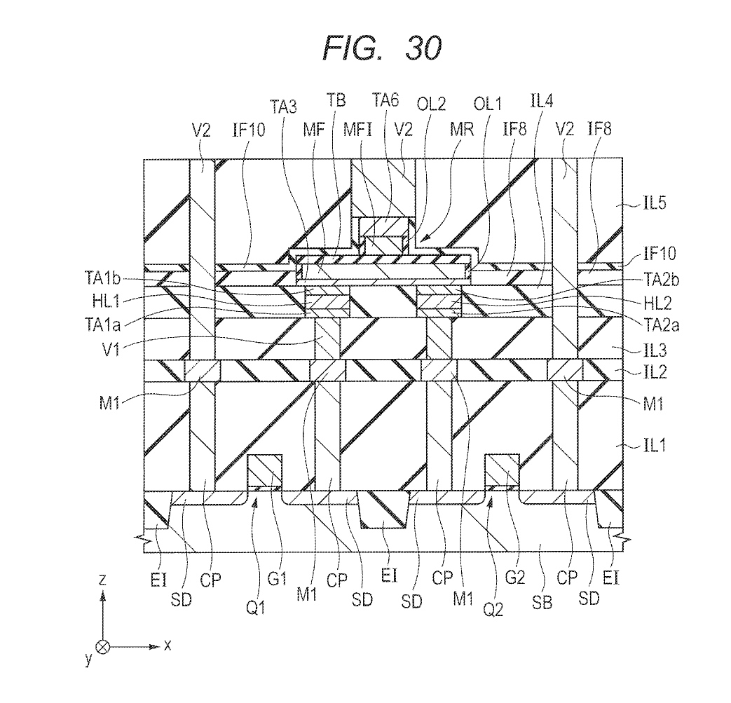

From the bottom surface of the via hole, the upper surface of the conductor film TA6 is exposed. In this step, another via hole is also formed in a region not shown in FIG. 28. The another via hole penetrates through the interlayer insulating film IL5, the insulating films IF10 and IF8, and the interlayer insulating films IL4 and IL3 and exposes the upper surface of the wiring M1 as shown in FIG. 30.

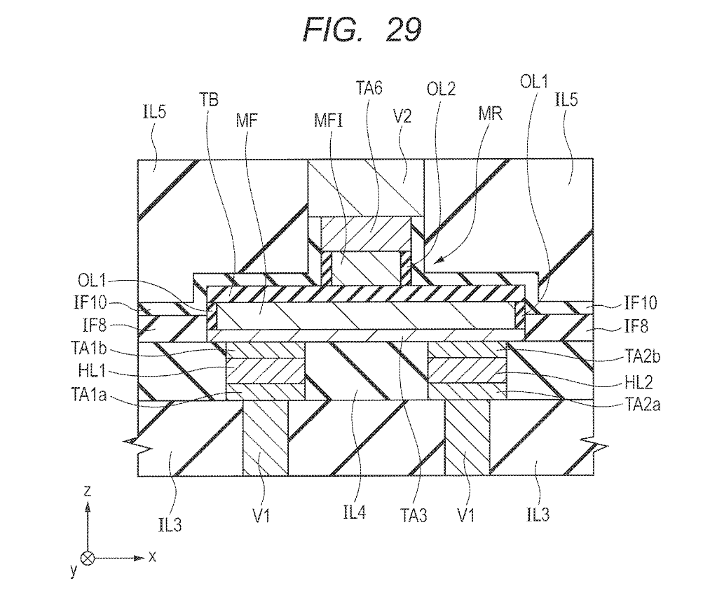

Next, as shown in FIGS. 29 and 30, the via hole is filled with a conductor film made mainly of copper (Cu) and formed on each of the interlayer insulating film IL5 and the conductor film TA6 by sputtering and plating. The conductor film on the interlayer insulating film IL5 is then removed using CMP to expose the upper surface of the interlayer insulating film IL5 and thereby, a via V2 made of the conductor film is formed in the via hole. In this step, in addition to the via V2, a via V2 is formed in the another via hole.

Although not illustrated here, a second wiring layer is formed on the interlayer insulating film IL5 and the via V2 by steps after formation thereof. Other wiring layers are formed over the second wiring layer to complete a semiconductor device having a memory cell of MRAM including the magnetoresistance effect element MR of the present embodiment. Operation methods of the MRAM of the present embodiment are as described referring to FIGS. 4 to 9.

### <Advantage of the Method of Manufacturing a Semiconductor Device of the Present Embodiment>

The advantage of the method of manufacturing a semiconductor device according to the present embodiment will next be described.

As described referring to FIGS. 40 and 41, there is a fear of the metal deposit MM, that has configured the magnetic layers MF and MFI, attaching to the side wall of the magnetoresistance effect element MRa during formation of the magnetoresistance effect element MRa by processing the magnetic layer MF, the tunnel barrier layer TB, and the magnetic layer MFI by dry etching (anisotropic etching). In this case, a leakage current flows via the metal deposit MM and interferes with normal operation of the magnetoresistance effect element MRa. As a result, the semiconductor device thus obtained has deteriorated reliability.

In the present embodiment, on the other hand, although the metal deposit MM is generated and attaches to each of the magnetic layers MF and MFI also in the steps described referring to FIGS. 20 and 24, plasma treatment is performed in a gas atmosphere containing carbon and oxygen as described above in FIGS. 25 and 26. By this plasma treatment, the metal deposit MM having conductivity reacts with carbon and oxygen configuring the gas to form a carbonyl group and a carbonyl compound containing the carbonyl group is then sublimed at a temperature of 104° C. or more in the plasma apparatus. The metal deposit MM is removed by this sublimation, making it possible to prevent generation of a leakage current and thereby prevent the magnetoresistance effect element MR from malfunctioning. The semiconductor device thus obtained can therefore have improved reliability.

By the above-described plasma treatment, the side wall of the magnetic layer MF is covered with the oxide film OL1 which is an insulating film made of an oxide of the magnetic layer MF and the side wall of the magnetic layer MFI is covered with the oxide film OL2 which is an insulating film made of an oxide of the magnetic layer MFI. These oxide films can prevent the metal deposit MM having conductivity from attaching to the respective surfaces of the magnetic layers MF and MFI and becoming a leakage path. The metal deposit MM that has remained without being removed during formation of a carbonyl group and sublimation is oxidized into an insulator so that generation of leakage can be prevented. The semiconductor device thus obtained can therefore have improved reliability.

Even when the magnetic layers MF and MFI are made of FeNi, the metal deposit MM made of Fe (iron) and the like becomes a carbonyl compound and is sublimed. The surface of the magnetoresistance effect element MR is covered with the oxide films OL1 and OL2 made of, for example, nickel oxide (NiO) or iron oxide (FeO, Fe₂O₃). The metal deposit MM is oxidized into an insulator. Generation of leakage in the magnetoresistance effect element MR can therefore be prevented.

As described above, in the method of manufacturing a semiconductor device according to the present embodiment, it is important to intentionally supply a gas containing carbon and oxygen (for example, a carbon oxide gas) and form a carbonyl compound sublimable at a relatively low temperature when the plasma treatment is performed.

Using, as a gas to be supplied in the plasma treatment, a gas containing, for example, methane (CH₄) and oxygen (O₂) makes it possible to form a carbonyl group and sublime the resulting carbonyl compound and further, to bring about an effect of oxidizing the side wall of the magnetoresistance effect element with oxygen (O₂).

It has been revealed by the test made by the present inventors that a leakage current can be reduced more by the plasma treatment with a carbon oxide gas than by the plasma treatment with a gas containing methane (CH₄) and oxygen (O₂). This is because a carbonyl group can be formed more easily when a carbon oxide gas in which carbon has bound to oxygen prior to supply to the plasma apparatus is used and a more marked metal oxide removal effect can be achieved by sublimation.

### Modification Example

As a modification example of the manufacturing method of a semiconductor device, the gas used for the plasma treatment described referring to FIGS. 25 and 26 may contain an oxygen (02) gas. An advantage similar to that of the present embodiment described referring to FIGS. 10 to 30 can be obtained by carrying out plasma treatment while supplying the plasma apparatus with a COx gas, that is, for example, either one or both of CO and CO₂ and an O₂ gas.

In addition, oxidization by the above-described plasma treatment can be enhanced further. In other words, the thickness of the oxide films OL1 and OL2 shown in FIGS. 25 and 26 is increased and the side wall of the magnetic layers MF and MFI can be covered more completely. As a result, generation of a leakage current can be prevented. Further, the metal deposit MM that has remained without being sublimed can be oxidized more completely to change it into an insulating film. Generation of a leakage current flowing via the metal deposit MM can therefore be prevented.

### Second Embodiment

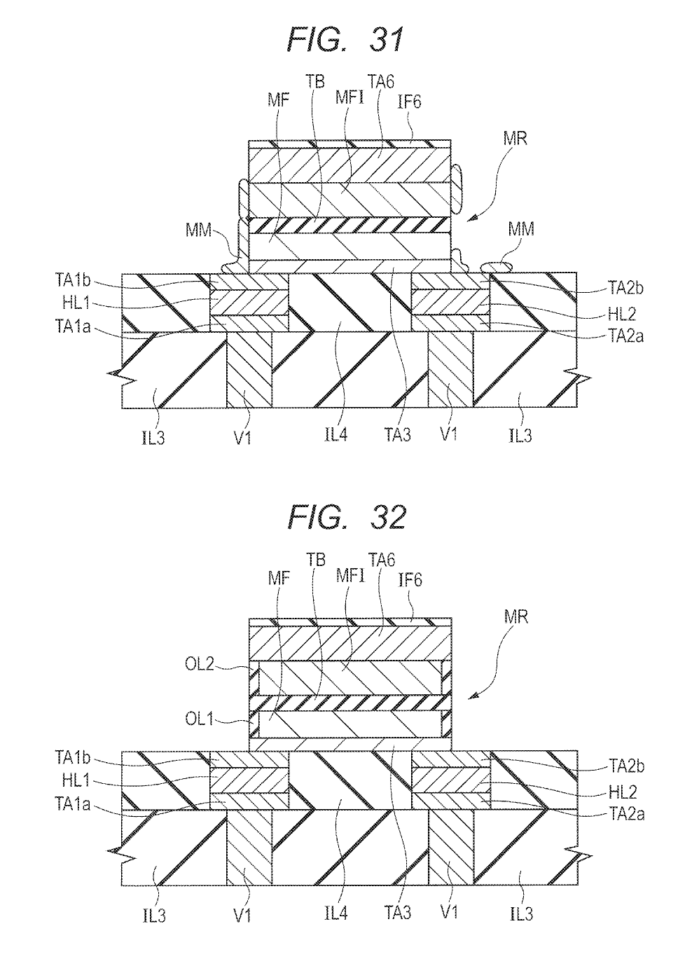

Next, formation of MRAM having a magnetoresistance effect element different in pattern from that of First Embodiment will be described. A method of manufacturing a semiconductor device according to Second Embodiment will be described referring to FIGS. 31 to 34. FIGS. 31 to 34 are cross-sectional views of the semiconductor device of the present embodiment during manufacturing steps thereof. FIGS. 31 to 34, similar to FIGS. 12 to 29, show only the cross-section of a main portion of a region above the first wiring layer.

First, steps similar to those described referring to FIGS. 10 to 18 are carried out. After patterning of the insulating film IF7 (refer to FIG. 18), dry etching (anisotropic etching) is then carried out with the insulating film IF7 as a mask as shown in FIG. 31 to process the insulating film IF6, the conductor film TA6, the magnetic layer MFI, the insulating layer IF5, the magnetic layer MF, and the conductor film TA3. Dry etching is carried out by plasma etching. A portion of the upper surface of each of the interlayer insulating film IL4 and the conductor films TA1b and TA2b is exposed by this etching.

A tunnel barrier layer TB comprised of the insulating layer IF5 is thereby formed. The present etching step is performed in order to form a final pattern of the magnetic layers MF and MFI and the tunnel barrier layer TB. A magnetoresistance effect element MR comprised of the magnetic layers MF and MFI and the tunnel barrier layer TB is thus formed. The description here is made while regarding the insulating film IF7 as a film to be removed. A metal deposit MM made of a metal that has configured the magnetic layers MF and MFI until removal by dry etching attaches to the side wall of the magnetic layer MF, the side wall of MFI, and the like.

A pattern of the stacked film including the magnetic layers MF and MFI and the tunnel barrier layer TB obtained by patterning covers the whole upper surface of each of the conductor film TA1b and the conductor film TA2b in the step described referring to FIG. 20 in First Embodiment, but due to a narrow width of the pattern in the present embodiment, a portion of the upper surface of each of the conductor film TA1b and the conductor film TA2b is covered with the pattern and the other portion is exposed from the pattern. What is different from the steps described above referring to FIGS. 10 to 20 in First Embodiment is only the width of the pattern of the stacked film including the magnetic layers MF and MFI and the tunnel barrier layer TB obtained by patterning.

Next, as shown in FIG. 32, plasma treatment described referring to FIGS. 25 and 26 is performed. By this treatment, the metal deposit MM reacts with a carbon oxide gas to form a carbonyl group and a carbonyl compound containing the carbonyl group is sublimed and removed. In addition, by the plasma treatment, an oxide film OL1 is formed on the side wall of the magnetic layer MF and an oxide film OL2 is formed on the side wall of the magnetic layer MFI. The metal deposit MM that has remained without being sublimed is oxidized. The plasma treatment conditions and the composition of the oxide films OL1 and OL2 are similar to those in First Embodiment.

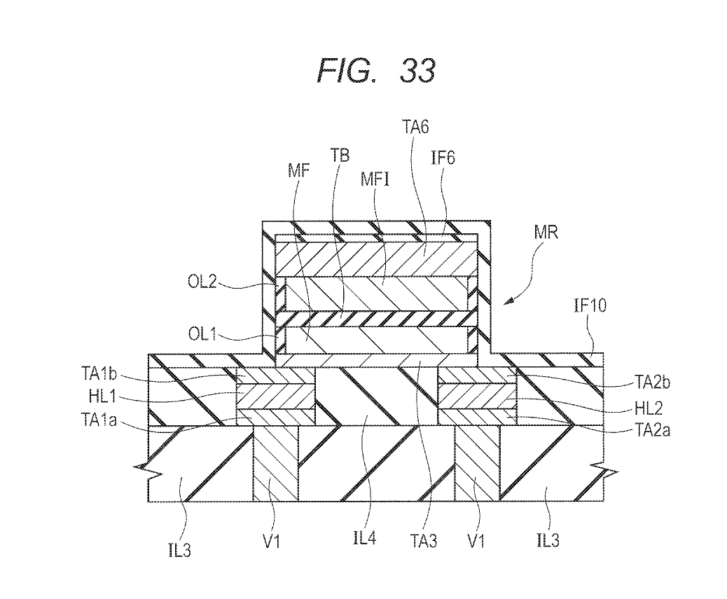

Next, as shown in FIG. 33, an insulating film IF10 made of, for example, a silicon nitride film is formed on each of the magnetoresistance effect element MR, the interlayer insulating film IL4, and the conductor films TA1b and TA2b by plasma CVD in the plasma apparatus used continuously from the above-described plasma treatment. An interlayer insulating film IL5 is then formed on the insulating film IF10 using, for example, CVD. The interlayer insulating film IL5 is made of, for example, a silicon oxide film. The upper surface of the interlayer insulating film IL5 is then polished using, for example, CVD to planarize it. During the polishing, the upper surface of the insulating film IF10 is not exposed.

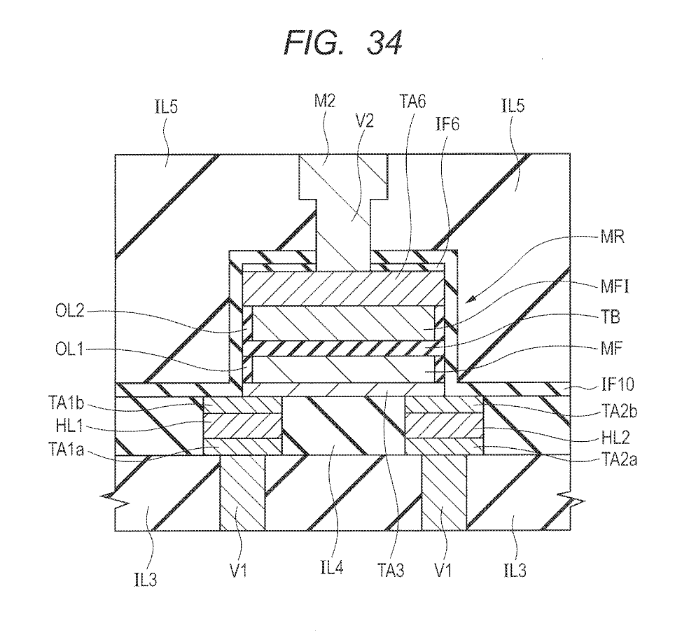

Next, as shown in FIG. 34, a via hole penetrating through the interlayer insulating film IL5 and the insulating film IF10 is formed using photolithography and dry etching. The upper surface of the conductor film TA6 is exposed from the bottom surface of the via hole. In this step, another via hole is formed in a region not shown in FIG. 28.

A wiring trench is then formed in the upper surface of the interlayer insulating film IL5 at a position overlapping, in plan view, with the region having the via hole therein by photolithography and dry etching. The wiring trench has a depth shallower than the via hole, and the bottom surface of the wiring trench does not reach the upper surface of the insulating film IF10 on the magnetoresistance effect element MR. Alternatively, the formation of the wiring trench may be followed by the formation of the via hole at the bottom surface of the wiring trench.

Next, as shown in FIGS. 29 and 30, a conductor film made mainly of copper (Cu) is formed on each of the interlayer insulating film IL5 and the conductor film TA6 by sputtering and plating to fill the via hole and the wiring trench therewith. Then, a via V2 made of the conductor film is formed in the via hole and a wiring M2 is formed in the wiring trench, by removing the conductor film on the interlayer insulating film IL5 and exposing the upper surface of the interlayer insulating film IL5 by CMP. This means that the via V2 and the wiring trench M2 thereabove are formed simultaneously by the so-called dual damascene process. The formation method of the wiring M2 by the dual damascene process may be applied to First Embodiment.

Although not illustrated here, a plurality of wiring layers is formed on the interlayer insulating film IL5 and the wiring M2 in the steps thereafter to complete a semiconductor device having MRAM including the magnetoresistance effect element MR of the present embodiment. In the MRAM of the present embodiment, different from that of First Embodiment in the shape of the magnetoresistance effect element MR, the magnetic layer MFI extends in the x-axis direction similar to the magnetic layer MF. The resulting device operates as a method described referring to FIGS. 4 to 9.

In First Embodiment, the stacked film including the magnetic layers MF and MFI and the tunnel barrier layer TB is etched twice to form the magnetoresistance effect element MR (refer to FIGS. 20 to 24), while in the present embodiment, as shown in FIG. 31, the magnetoresistance effect element MR is formed by single etching. Even in such a case, the metal deposit MM is formed by processing the stacked film and becomes a cause for generation of a leakage current. By plasma treatment performed after the etching, the metal deposit MM can be removed and generation of a leakage current can be prevented by the formation of the oxide films OL1 and OL2 and oxidization of the metal deposit MM. This means that the present embodiment can bring about an advantage similar to that of First Embodiment.

### Third Embodiment

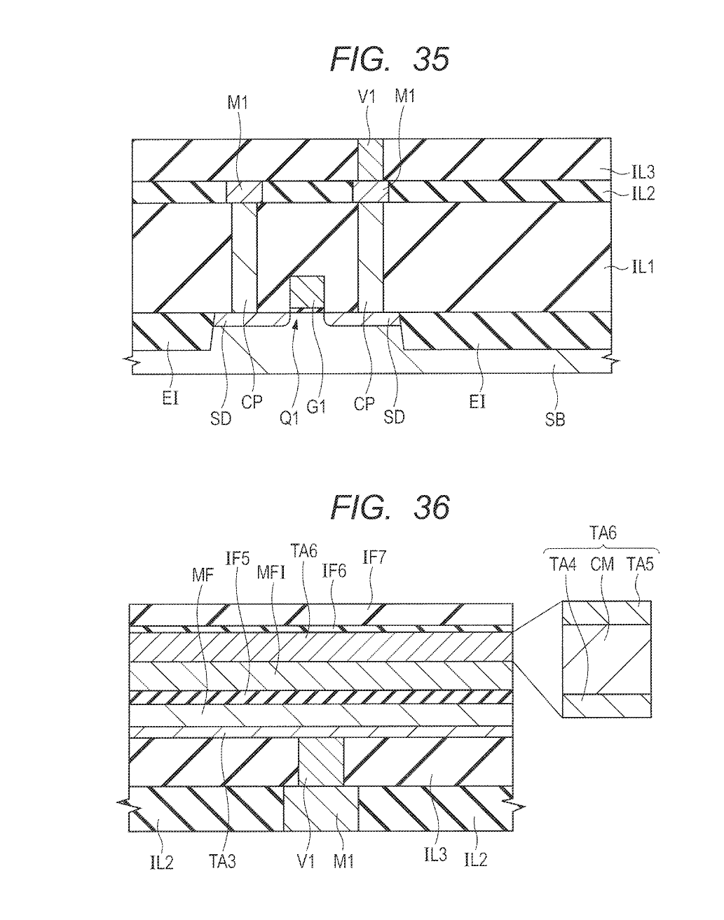

Next, formation of an STT (spin transfer torque) type MRAM will be described. In the MRAM of First Embodiment and Second Embodiment, two transistors are coupled to the bottom portion of the magnetoresistance effect element. The STT type MRAM of the present embodiment is, on the other hand, a nonvolatile memory in which one transistor is coupled to the bottom portion of the magnetoresistance effect element. A method of manufacturing a semiconductor device according to Third Embodiment will hereinafter be described referring to FIGS. 35 to 39. FIGS. 35 to 39 are cross-sectional views of the semiconductor device of the present embodiment during the manufacturing steps thereof. FIG. 35 shows a semiconductor substrate and a transistor formed on the upper surface thereof. FIGS. 36 to 39 show only the cross-section of a main portion, that is, a first wiring layer and a region above the first wiring layer.

In the manufacturing steps of the semiconductor device of the present embodiment, a MOS transistor Q1, an interlayer insulating film IL1 on the MOS transistor Q1, a first wiring layer on the interlayer insulating film IL1, and a via V1 on the first wiring layer are formed on the semiconductor substrate SB by carrying out steps similar to those described referring to FIGS. 10 and 11. In the present embodiment, different from FIGS. 10 and 11, only one MOS transistor Q1 is formed for one magnetoresistance effect element MR formed later. A contact plug CP is coupled to one of source and drain regions SD configuring the MOS transistor Q1. A wiring M1 is coupled to the upper surface of the contact plug CP and a via V1 is coupled to the upper surface of the wiring M1.

Next as shown in FIG. 36, a film formation step similar to that described referring to FIG. 18 is performed. Described specifically, a conductor film TA3, a magnetic layer (magnetic free layer) MF, an insulating layer IF5, a magnetic layer (magnetic pinned layer) MFI, a conductor film TA6, and insulating films IF6 and IF7 are formed successively on the interlayer insulating film IL3 and the via V1, for example, by sputtering and CVD. The conductor film TA6 has, as shown in an enlarged view on the right side of the drawing, a stacked structure including the conductor films TA4, CM, and TA5 formed successively on the magnetic layer MFI. The material of each of the films configuring the stacked film is similar to that of First Embodiment described referring to FIG. 18.

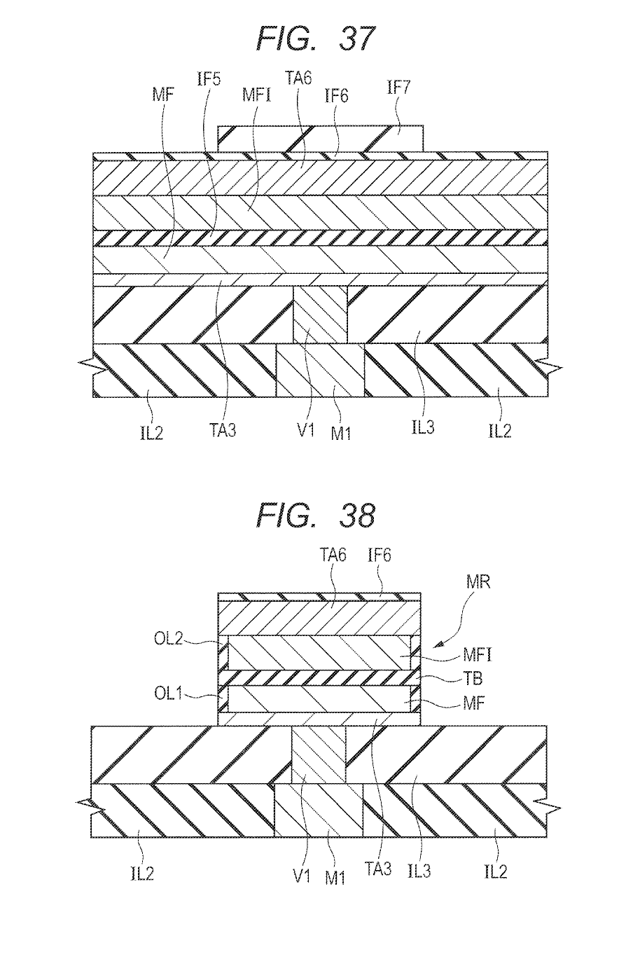

Next, as shown in FIG. 37, a step similar to that described referring to FIG. 19 is performed to process the insulating film IF7 and thereby expose the upper surface of a portion of the insulating film IF6. The pattern of the insulating film IF7 formed thereby overlaps with the via V1 in plan view.

Next, as shown in FIG. 38, a step similar to that described referring to FIG. 20 is performed to carry out dry etching (anisotropic etching) with the insulating film IF7 as a hard mask. The insulating film IF6, the conductor film TA6, the magnetic layer MFI, the insulating layer IF5, the magnetic layer MF, and the conductor film TA3 are processed by the dry etching. The dry etching is performed by plasma etching. The plasma etching is performed with a gas such as methanol (CH₃OH), ethanol (C₃H₆O), argon (Ar) or chlorine (Cl).

By the above etching, a portion of the upper surface of the interlayer insulating film IL3 is exposed, and also a tunnel barrier layer TB comprised of the insulating layer IF5 is formed. The above-described etching step is performed in order to form a final pattern of the magnetic layers MF and MFI, and the tunnel barrier layer TB. These magnetic layers MF and MFI and the tunnel barrier layer TB processed by the etching step configure the magnetoresistance effect element MR. The description here is made while regarding the insulating film IF7 as a film to be removed.

In this step, by the dry etching, a metal deposit (not shown) is formed as in First Embodiment and it attaches to the side wall of the magnetic layer MF, the side wall of the MFI, and the like.

Plasma treatment similar to that described referring to FIGS. 25 and 26 is then performed. By this treatment, the metal deposit is sublimed or oxidized. The side wall of the magnetic layer MF is covered with the oxide film OL1 and the side wall of the MFI is covered with the oxide film OL2.

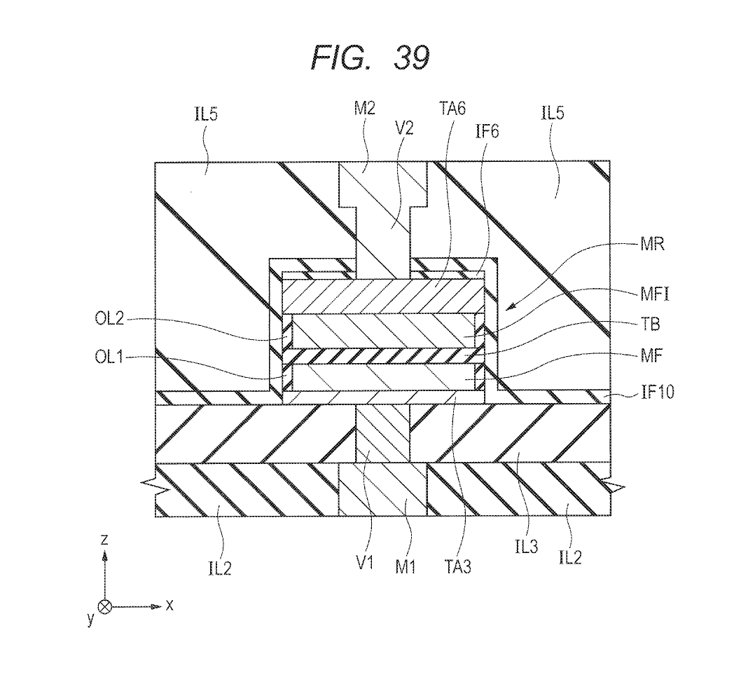

Next, as shown in FIG. 39, steps similar to those described referring to FIGS. 27 to 30 are performed to cover the magnetoresistance effect element MR with the insulating film IF10 and the interlayer insulating film IL5 and form a via V2 penetrating through the interlayer insulating film IL5 and the insulating films IF10 and IF6 and coupled to the conductor film TA6.

Although not shown here, by steps thereafter, a second wiring layer is formed on the interlayer insulating film IL5 and the via V2. By forming another wiring layer on the second wiring layer, a semiconductor device having MRAM including the magnetoresistance effect element MR of the present embodiment is completed.

The STT type MRAM of the present embodiment writes data by changing the magnetization direction of the magnetic layer (magnetic free layer) MF configuring the magnetoresistance effect element MR by the direction of a current flowing through the magnetoresistance effect element MR. The magnetization directions of the magnetic layer MF and the magnetic layer MFI are parallel to each other in a direction along the main surface of the semiconductor substrate SB. This means that the magnetization directions of the magnetic layer MF and the magnetic layer MFI are along the x-axis direction. The magnetization direction of the magnetic layer MF can however be reversed by torque action of electron spins generated by applying a current to the magnetoresistance effect element MR.

When the magnetization direction of the magnetic layer MF is almost opposite to that of the magnetic layer MFI, that is, substantially antiparallel to each other, the magnetoresistance effect element MR has reduced resistance value. On the other hand, when the magnetization direction of the magnetic layer MF and that of the magnetic layer MFI are substantially same, the magnetoresistance effect MR has increased resistance value. The STT type MRAM can read which data “0” or data “1” is written therein by finding a difference in magnitude of the resistance value of the magnetoresistance effect element MR.

In the present embodiment, the metal deposit is sublimed or oxidized by carrying out the plasma treatment described above referring to FIG. 38. In addition, by the plasma treatment, the side wall of the magnetic layer MF is covered with the oxide film OL1 and the side wall of the magnetic layer MFI is covered with the oxide film OL2. This makes it possible to prevent occurrence of a leakage current due to re-deposition of a metal deposit between the magnetic layer MF and the magnetic layer MFI. In short, an advantage similar to that of First Embodiment can be obtained.

Alternatively, the magnetic layer (magnetic free layer) MF may be placed on the tunnel barrier layer TB and the magnetic layer (magnetic pinned layer) MFI may be placed below the tunnel barrier layer TB.

The invention made by the present inventors has been described specifically based on some embodiments. It is however needless to say that the present invention is not limited to the above-described embodiments, but can be changed variously without departing from the gist of the invention.

What is claimed is:

1. A method of manufacturing a semiconductor device equipped with a memory cell including a magnetoresistance effect element, comprising the steps of:
(a) stacking a first magnetic layer, an oxidized magnetic layer, and a second magnetic layer successively to form a stacked film;
(b) processing the first magnetic layer, the oxidized magnetic layer, and the second magnetic layer by first anisotropic etching to form the magnetoresistance effect element having the stacked film; and
(c) subjecting the magnetoresistance effect element to plasma treatment in an atmosphere of a gas containing carbon and oxygen.

2. The method of manufacturing a semiconductor device according to claim 1,
wherein in the step (b), a conductor substance configuring a portion of the first magnetic layer or the second magnetic layer is etched by the first anisotropic etching and then attaches to a surface of the magnetoresistance effect element obtained by being processed by the first anisotropic etching; and
wherein in the step (c), the plasma treatment is performed to remove the conductor substance that has attached to the surface of the magnetoresistance effect element.

3. The method of manufacturing a semiconductor device according to claim 2,
wherein in the step (c), the conductor substance that has attached to the surface of the magnetoresistance effect element reacts with the gas to form a carbonyl compound, and the carbonyl compound is sublimed to remove the conductor substance.

4. The method of manufacturing a semiconductor device according to claim 3,
wherein in the step (c), a temperature in a plasma apparatus in which the plasma treatment is performed is set at 104° C. or more.

5. The method of manufacturing a semiconductor device according to claim 1,
wherein in the step (c), the plasma treatment is performed to oxidize a side wall of the first magnetic layer to form a first oxidized insulating film and oxidize a side wall of the second magnetic layer to form a second oxidized insulating film.

6. The method of manufacturing a semiconductor device according to claim 1,
wherein in the step (b), a conductor substance configuring a portion of the first magnetic layer or the second magnetic layer is etched by the first anisotropic etching and then attaches to a surface of the magnetoresistance effect element processed by the first anisotropic etching, and
wherein in the step (c), the plasma treatment is performed to oxidize the conductor substance that has attached to the surface of the magnetoresistance effect element.

7. The method of manufacturing a semiconductor device according to claim 1,
wherein the first magnetic layer or the second magnetic layer contains cobalt or iron.

8. The method of manufacturing a semiconductor device according to claim 1,
wherein the gas contains a carbon oxide gas.

9. The method of manufacturing a semiconductor device according to claim 1,
wherein the gas contains an O₂ gas.

10. The method of manufacturing a semiconductor device according to claim 3,
wherein the step (b) comprises the sub-steps of:
(b1) processing the first magnetic layer by second anisotropic etching; and
(b2) processing the second magnetic layer by third anisotropic etching,
wherein the oxidized magnetic layer is processed in the step (b1) or the step (b2),
wherein the step (b1) and the step (b2) are carried out to form the magnetoresistance effect element,
wherein a width of the first magnetic layer configuring the magnetoresistance effect element is greater than a width of the second magnetic layer configuring the magnetoresistance effect element, in a direction perpendicular to a stacking direction of the stacked film.

11. A semiconductor device, comprising:
a first magnetic layer;
an oxidized magnetic layer formed over the first magnetic layer;
a second magnetic layer formed on the oxidized magnetic layer;
a first oxidized insulating film covering a side wall of the first magnetic layer; and
a second oxidized insulating film covering a side wall of the second magnetic layer.

12. The semiconductor device according to claim 11;
wherein the first oxidized insulating film contains an oxide of a composition of the first magnetic layer and the second oxidized insulating film contains an oxide of a composition of the second magnetic layer.

13. The semiconductor device according to claim 11,
wherein the first magnetic layer and the second magnetic layer contain cobalt or iron and the first oxidized insulating film and the second oxidized insulating film contain cobalt oxide or iron oxide.

14. The semiconductor device according to claim 11,
wherein a width of the first magnetic layer is greater than a width of the second magnetic layer in a direction perpendicular to a stacking direction of the first magnetic layer, the oxidized magnetic layer, and the second magnetic layer.

15. The semiconductor device according to claim 14,
wherein the first magnetic layer is, at an upper surface at both end portions thereof, not covered with the second magnetic layer but covered with the oxidized magnetic layer.
